(19) United States
(12) Patent Application Publication
(10) Pub. No.: US 2007/0238252 A1
(43) Pub. Date: Oct. 11, 2007

(54) Cosmic particle ignition of artificially ionized plasma patterns in the atmosphere

(76) Inventor: Bernard Eastlund, La Jolla, CA (US)

Correspondence Address: Bernard Eastlund, 10327 Tuxford Dr, ST. Louis, MO, 63146, US

(21) Appl. No.: 11/219,982

(22) Filed: Sep. 6, 2005

(51) Int. Cl. H01L 21/336

(52) U.S. Cl. 438/282

(57) ABSTRACT

This invention is a method and apparatus for creating artificially ionized regions in the atmosphere utilizing ionization trails of cosmic rays and micro-meteors to ignite plasma patterns in electric field patterns formed by ground based electromagnetic wave radiators. The applications are useful for telecommunications, weather control, lightening protection and defense applications. The invention lowers the power requirements for forming artificial ionized regions in the atmosphere by a factor of up to 1600 times lower than those required in existing designs and projections for creation of artificial ionized regions in the atmosphere.

### BACKGROUND OF THE INVENTION

1. Field of Invention

This invention generally relates to generation of artificially ionized plasma patterns in the atmosphere and to lowering the cost and enhancing the reliability of applications such as telecommunications systems.

2. Prior Art

Various methods and apparatus have been suggested for creation of localized regions of ionized gas in the atmosphere for the purpose of communications enhancements and other purposes. In particular, Eastlund in U.S. Pat. Nos. 4,712,155, 4,686,605 and 5,038,664 suggested creation of an artificial ionospheric mirror using electron cyclotron resonance heating from directed electromagnetic waves of 1 to 10 Mhz from a large phased array antenna located in Alaska. The power level required for such an operation was very large, over a billion watts.

Subsequent work by ARCO's then subsidiary APTI resulted in studies of the details of creation of such an ionized layer with a single phased array as described in Air Force Geophysics Laboratory Reports and in a Patent by Peter Koert. (Short et al, System Concept and Analysis for an Artificial Ionospheric Mirror (AIM) Radar, Geophysics Laboratory Report GL-TR-90-0267, Aug. 31, 1990; Peter Koert, U.S. Pat. No. 5,041,834)

These studies showed that the effective radiated power required (ERP) was above 160 to 170 DBW (Decibels per watt). For a 500 meter diameter antenna that would require a signal level of 3×10ˆ8 watts and would require an expense in the 100's of millions of dollars. No atmospheric testing of such a system has been reported.

Gurevich and his group developed an alternative method of creation of ionized layers with crossed beams. (Borisov, N. D. and Gurevich, A. V. Geomagnetism and Aeronomy, Vol. 20, No. 5, 1980) Vikharev et al estimated the power requirement for such a system to be over 4×10ˆ9 watts per beam with a system ERP of 160 to 170 DBW. (Vikharev, A., et al, American Geophysical Union, 1994) These crossed beam concepts required power levels of 4×10⁹ watts per transmitter and 60 meter diameter antennas. Such systems would be extremely expensive to construct. No atmospheric testing of such a system has been reported.

The reason for the large power requirements is the high value of the electric field needed to “breakdown” the air and create an ionized region. A number of authors have analyzed the required value and it ranges from 24 kilovolts per cm at sea level to about 350 kv/cm at an altitude of 40 km. This translates into 1500 Megawatts/meterˆ2 at an sea level and 2.3 Megawatts/meter² at an altitude of 30 km. (Zhang, Thesis, Polytechnic University, 1991; Jordan, Ulf, Microwave Breakdown Physics and Applications, Thesis, Department of Radio and Space Science, Chalmers University of Technology, Sweden, 2005; Papadopoulos, K. et al, Ionization Rates for Atmospheric and Ionospheric Breakdown, Journal of Geophysical Research, Vol. 98, No. A10 pp 17,593-17,596, Oct. 1, 1993)

These high power requirements and the high cost involved has been a limitation on practical applications of artificial ionized regions of plasma in the atmosphere. The high power requirements have also limited studies of artificial ionized plasma regions for communications to the range of 30 to 40 km, where the breakdown electric field is a minimum.

### OBJECTIVES

The objective of this invention is to provide a method and apparatus for economically and reliably generating artificially ionized plasma patterns in the air for a wide range of practical applications.

Telecommunications applications include enhancement of service quality in existing cellular networks, a short haul cellular system, a city wide cellular system, and a novel long haul communications system.

Weather control applications include a method of localized heating of the troposphere that can generate acoustic atmospheric waves or gravitational atmospheric waves for modification of the steering winds that influence weather phenomena. Another application is to provide ionized plasma patterns that can influence the charge distribution in meso-cyclones and provide a novel means of lightening protection.

### SUMMARY

This invention is a method and apparatus that lowers the practical electric field for air breakdown by a factor of up to 40 and lowers the power required for producing artificial ionized regions in the air by a factor of up to 1600. This difference is sufficient to make production of such artificial ionized regions practical with inexpensive and available power sources.

This invention also removes the altitude limitation on producing artificial ionized regions in the air and allows such regions to be produced from sea level to about 80 km.

This invention is a method and apparatus that makes use of electrons produced in the atmosphere by cosmic rays and by meteor bursts to lower the electric field required for air breakdown. Another term for air breakdown that is used to describe initiation and generation of a plasma in a microwave lamp is “plasma ignition”. The process described in this invention is therefore referred to as “cosmic plasma ignition.”

A principal embodiment is to use cosmic particles, such as cosmic ray generated electrons or micro-meteor trails, to ignite an artificial ionized region “plasma pattern” in the air. The method is to use high power electromagnetic wave radiator to create a contiguous pattern of high electric fields (The “field pattern”) in the atmosphere at a distance of between sea level and 80,000 meters and to maintain the field pattern until one or more cosmic particles such as cosmic ray electrons or micro-meteors create a columnar trail of ionized air to ignite breakdown somewhere within the field pattern. The electric fields in the field pattern accelerate the electrons in the columnar trail in all directions and produce air breakdown throughout the contiguous volume of the field pattern. The field pattern is continuously maintained during the breakdown process. The electric field intensity required for air breakdown using this method is up to 40 times lower than the value for breakdown in ambient air and the power required is lower by a factor of up to 1600. This lower power requirement makes concepts such as artificial ionospheric mirrors for communications practical. Many other applications include a potential method of lightening protection and a new approach to modifying weather related phenomena.

Another principal embodiment of this patent for utilizing cosmic particles to ignite plasma patterns in electrical field patterns in the atmosphere is by first detecting the position of the cosmic particle ionization trail with a detector array, then triggering an electromagnetic wave radiator to focus the electromagnetic waves on a region in the air that includes the ionization trail of the cosmic particle. The electromagnetic wave generator holds the electric field pattern constant while the cosmic particle ionization trail ignites electrical breakdown of the air and fills the electric field pattern with plasma to create a plasma pattern. The advantage of this method is to create an artificially ionized region of the air called a plasma pattern at a much lower power and cost than projected to be required by concepts relying on ambient air breakdown.

Another principal embodiment is to maintain the plasma pattern by continuously irradiating the plasma pattern with electromagnetic waves at a power level sufficient to maintain the plasma electron density at the value required by the desired application. Another principal method of this patent is to reconfigure the size or shape of the plasma pattern after it is established by modifying the electric field pattern. This can be done on a stationary or a dynamic basis. An example of a stationary basis method would be to change the focal pattern of the electromagnetic wave generator. An example of changing on a dynamic basis would be to change the focal position of the antenna by changing the frequency and the phase of the electromagnetic radiation generated by each radiating element of the array.

Another principal embodiment is to change the physical properties of the plasma pattern such as electromagnetic wave reflectivity, electrical conductivity and electromagnetic wave absorption varying the power level of the high power electromagnetic radiation projected from an electromagnetic wave radiator that create the contiguous pattern of high electric fields. Potential applications include use of the reflectivity of the plasma pattern for communications, the electrical conductivity for lightening protection and the absorption properties for atmospheric heating.

Another principal embodiment is to irradiate the plasma pattern with electromagnetic radiation projected from antennas that have a frequency higher than the electromagnetic radiation used to create the plasma layer to transfer energy to the region of air in or near the plasma pattern as a means of thermodynamically heating the air. Such a technique can be used to generate heated air regions and to generate acoustic waves and gravity waves in the atmosphere for weather modification purposes.

Another principal embodiment is to create multiple plasma patterns using more than one electromagnetic radiation projecting antenna system. An application of such a multiple plasma layer system would be to use two plasma patterns spaced horizontally apart at an altitude above the site to be protected, as electrically conductive electrodes to cause lightening to occur in an air to air trajectory rather than an air to ground trajectory thus protecting individuals on golf courses and beaches and other sensitive areas.

Another principal embodiment of this patent is to enhance cellular communication systems by producing disc shaped plasma patterns at altitudes of at least 10,000 meters over one or more existing cellular communications towers.

Another principal embodiment of this patent is to provide a short haul cellular telecommunications systems by producing disc shaped plasma patterns at altitudes of at least 10,000 meters and the use of at least one cellular base station with an upward pointing antenna.

Another principal embodiment of this patent is a city wide cellular communications system by producing a disc shaped plasma pattern at altitudes of at least 30,000 meters and the use of at least one cellular base station with an upward pointing antenna. Another principal embodiment of this patent is to provide a strong signal for city wide cellular communication by producing five disc shaped plasma pattern in a roughly parabolic pattern at an altitude of at least 30,000 meters and the use of at least one cellular base station with an upward pointing antenna. The additional gain provided by this system could make it possible to provide very high data rates to cellular equipment, possibly giving a WI FI connection to a whole city.

Another principal embodiment of this invention is to provide a long haul communication system by erecting shaped plasma patterns at two different locations on the earth's surface, each pattern located at an altitude of 80,000 meters and to use a base station at each location to send and receive telecommunications signals.

Another principal embodiment of this invention is a portable system for city wide communication. The individual phased array radiating elements have the capability to vary the frequency and phase of the electromagnetic wave generator and to point the electromagnetic radiation in the proper direction. Such a system would be useful for establishing cellular communication in natural disasters.

Another principal embodiment is to irradiate the plasma pattern with electromagnetic radiation projected from antennas that have a frequencies lower than the electromagnetic radiation used to create the plasma layer to accelerate electrons on the surface of the plasma layer to high energy. Such layers could be a source of high energy electrons for communications or military applications.

This invention makes practical many applications that derive from production of plasma patterns in the air.

### FIGURES

FIG. 1 Schematic Drawing of a Disc Shaped Field Pattern at an altitude h

FIG. 2 Block Diagram of Electromagnetic Wave Radiator

FIG. 3 Schematic Drawing of Crossed Beam Field Pattern

FIG. 4 Schematic of Cosmic Particle Intersecting Disc Shaped Field Pattern

FIG. 5 Photograph of Cosmic Ray Ionization Trail in Microwave Spark Chamber

FIG. 6 Ambient Breakdown Electric Fields in Air-Zhang Thesis

FIG. 7 Conversion of Pressure to Altitude-U.S. Standard Atmospheric Model

FIG. 8 Additional Ambient Air Breakdown Electric Fields

FIG. 9 Cosmic Ray Electron Flux vs. Altitude in KM.

FIG. 10 Meteor Trail Schematic

FIG. 11 Meteor Trail Electron Densities

FIG. 12 Numerical Simulation Results Partially Formed Plasma Pattern

FIG. 13 Numerical Simulation Results Fully Formed Plasma Pattern

FIG. 14 Trigger Method Sequence

FIG. 15 Meteor Detector Schematic

FIG. 16 Cell Phone Tower Enhancement Schematic

FIG. 17 Short Haul Cellular System

FIG. 18 City Wide Cellular System Schematic

FIG. 19 Shaped Five Panel Plasma Pattern

FIG. 20 Line of Sight Distance Between Two High Altitude Antenna above the Earth's Surface

FIG. 21 Long Haul Telecommunications Reflector at High Altitude

FIG. 22 Plasma Patterns as Air Heaters

FIG. 23 Gravitational Wave Model

FIG. 24 Plasma Pattern Short Circuiting Charge in a Meso-cyclone

FIG. 25 Two Plasma Patterns to Short Circuit Lightening

FIG. 26 Portable Wide Area Communications System

FIG. 27 Portable Phased Array Radiating Element

### DESCRIPTION

Method for Ignition of Air Breakdown to Produce Artificial Ionized Plasma Patterns in the Atmosphere

Top Level Description

The high critical electric field associated with ambient air breakdown and creation of artificial ionized plasmas in the atmosphere has required power levels too high for practical applications such as for reflection of radar waves. Cosmic particles such as cosmic rays and micro meteors produce columnar trails of ionization in the atmosphere that reduce the critical electric field for air breakdown. The method of this patent can be called “cosmic particle ignition” because it utilizes cosmic particles such as cosmic rays and micro-meteors to produce plasma patterns. In some circumstances, the reduction of the electric field can be a factor of 40, leading to a reduction of power requirements of a factor of up to 1600.

A principal embodiment of this patent is a method of creating artificial ionization regions in air at reduced critical electric fields by sequencing the timing of establishment of an electric field pattern in the air and the arrival time of cosmic particle ionization trails within the electric field pattern. For applications less than 40,000 meters, the relevant ionization trails are those produced by cosmic ray secondary electrons and for applications greater than 70,000 meters the relevant ionization trails are produced by micro meteors.

The first step of sequence for producing an artificially ionized plasma pattern in the atmosphere is to establish an electric field pattern in the air at an altitude h, by beaming electromagnetic waves from an electromagnetic wave radiator. The magnitude of the electric field in the pattern is the reduced electric field for air breakdown caused by ionization tracks. The next step is to ignite a plasma in the field pattern by holding the field pattern constant while waiting for one or more cosmic ray generated electrons or micro-meteors to intersect the field pattern and create a columnar trail of ionized air within the field pattern, resulting in initiation of the ignition process that causes air breakdown throughout the volume of the field pattern to create a “plasma pattern.” The electric fields in the field pattern accelerate the electrons in the columnar ionization trail in all directions and propagate the plasma throughout the volume of the field pattern. The waiting period is called the “ignition time”. The result of the application of this method is the creation of an artificial ionized region which fills the field pattern with plasma. We refer to this region as the “plasma pattern.”

Another principal embodiment of this patent for utilizing cosmic particles to ignite plasma patterns in electrical field patterns in the atmosphere is by first detecting the position of the cosmic particle ionization trail with a detector array, then triggering an electromagnetic wave radiator to focus the electromagnetic waves on a region in the air that includes the ionization trail of the cosmic particle. The electromagnetic wave generator holds the electric field pattern constant while the cosmic particle ionization trail ignites electrical breakdown of the air and fills the electric field pattern with plasma to create a plasma pattern. The advantage of this method is to create an artificially ionized region of the air called a plasma pattern at a much lower power and cost than projected to be required by concepts relying on ambient air breakdown.

Quantitative details of the physics and engineering aspects are presented in the Technical Issues section, and specific apparatus configurations are described.

Such plasma patterns can have a wide range of applications in communications, lightening protection, weather modification and defense purposes.

Detailed Description of the Method for Establishing a Plasma Pattern with Cosmic Particle Ignition

First Step—Establishment of Field Pattern

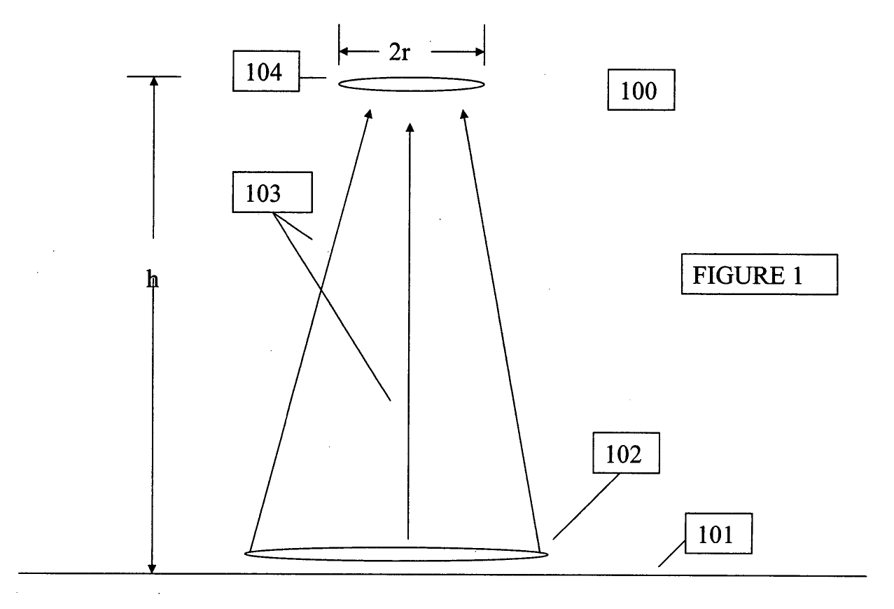

FIG. 1 is a schematic drawing of disc shaped field pattern 100 at an altitude h above the earth's surface. An electromagnetic wave radiator 102 beams electromagnetic waves in the electromagnetic wave propagation direction 103 to create a field pattern 104 which is a disc shaped pattern with a radius, r. The thickness of the disc shaped pattern 104 is initially on the order of many meters commensurate with the focal depth of the antenna pattern.

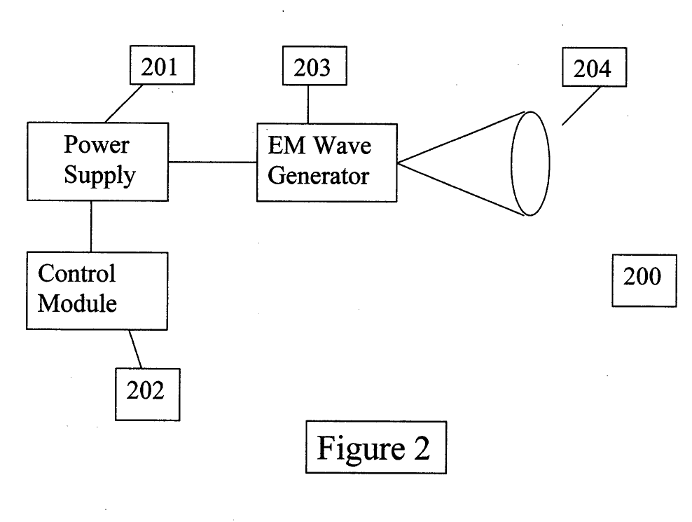

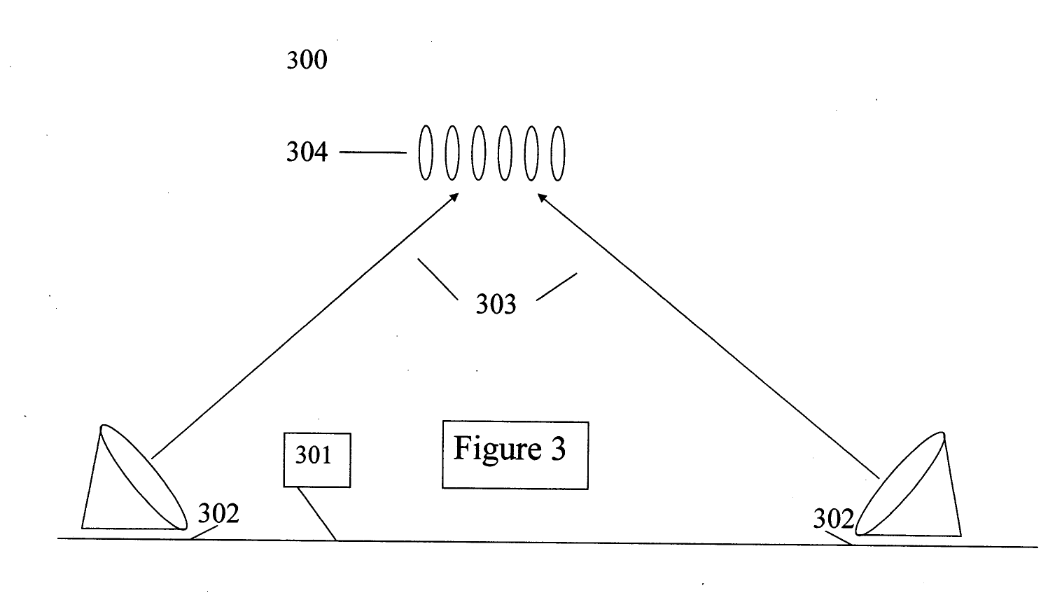

FIG. 2 is a block diagram of the system components of the electromagnetic wave radiator 102. It consists of a power supply 201, a control module 202 and electromagnetic wave generator 203 with a frequency ω and an antenna 204. The antenna can also be a phased array, with many separate radiating elements, a horn, a slot, or any other radiating geometry. The electromagnetic wave generator 203 can be a magnetron, klystron, gyrotron or a high power pulsed microwave source such as SINUS. The field pattern can be generated in a variety of shapes depending on the choice of antenna and electromagnetic wave generator. FIG. 3 is a schematic drawing of a field pattern generated by crossing the electromagnetic waves from two separated electromagnetic wave radiators 301. The electromagnetic wave generator can be pulsed with a pulse duration τₚᵤₗₛₑ, and a repetition frequency, fᵣₑₚ, or it can be steady state, CW. The field pattern generating system 300 can include more than two electromagnetic radiators and the field patterns can be complex as will be shown in the applications described in the patent.

Second Step—o Hold Field Pattern Constant Until Ionization Trail Occurs

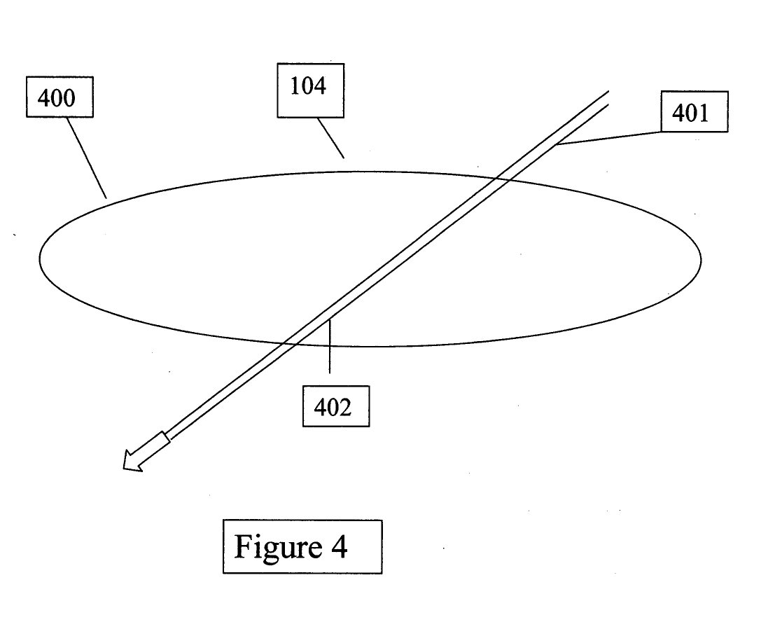

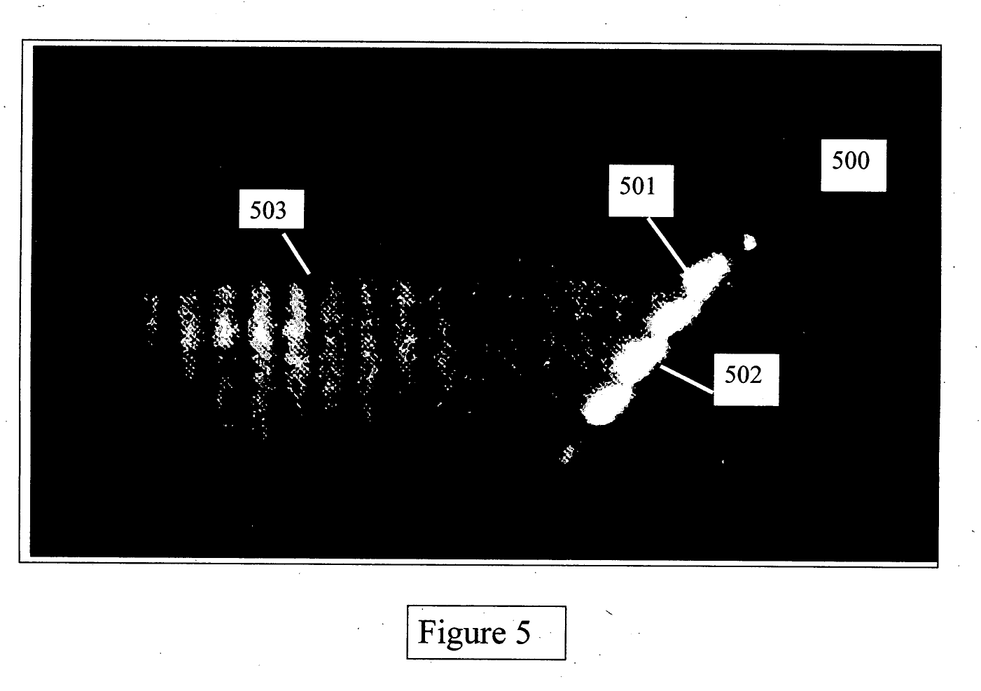

The field pattern is held constant by the control system 202 until one or more ionization trails intersect the column and create columnar trails of ionization that initiate the air breakdown process. The waiting time period is called the “ignition time” and it is determined by the time dependent flux of ionization trails generated by cosmic rays below 30,000 meters and by micro-meteors above 70,000 meters. The “ignition time” τ_{ign} is a function of the time dependent cosmic ray generated electron flux, the duration of the EM wave pulse τₚ, the repetition rate fᵣₑₚ and the area of the field pattern. Equation 3 in the Technical Details describes the functional relationship between these quantities. FIG. 4 is a schematic of an ionization trail intersecting a disc shaped field pattern 104. The cosmic particle intersects the field pattern 104 creating a columnar ionization trail 402. The ionization trail is initially a series of small ionized regions, each with initial dimensions of about 0.001 cm with electron number densities above 10¹⁰ electrons/cm³. Cosmic rays have been detected at sea level by microwave field patterns. FIG. 5 is a photograph of a cosmic ray ionization trail 500 in the field pattern of a microwave waveguide. The cosmic ray particle path 501 is highlighted by a series of dots which is the columnar ionization trail 501. The microwave frequency was 1.3 Ghz and the waveguide dimensions were 7 cm by 17 cm. The electromagnetic pulse generating the field pattern had pulse duration τₚᵤₗₛₑ of 250 nanoseconds. This figure is taken from a paper by Kustom et al (Nuclear Instruments and Methods, Vol. 118, pp. 203-211, 1974)

If the microwaves were to have been left on for a longer period of time, the electrons in these small ionized regions would be quickly accelerated causing multiplication of electrons by collisions with air molecules to create air breakdown and rapidly fill the field pattern region with plasma, creating a plasma pattern. This FIG. 5 directly demonstrates the effectiveness of the method of cosmic particle ignition of this invention.

Underlying Physics and Procedural Details

Electrical Breakdown in Ambient Air

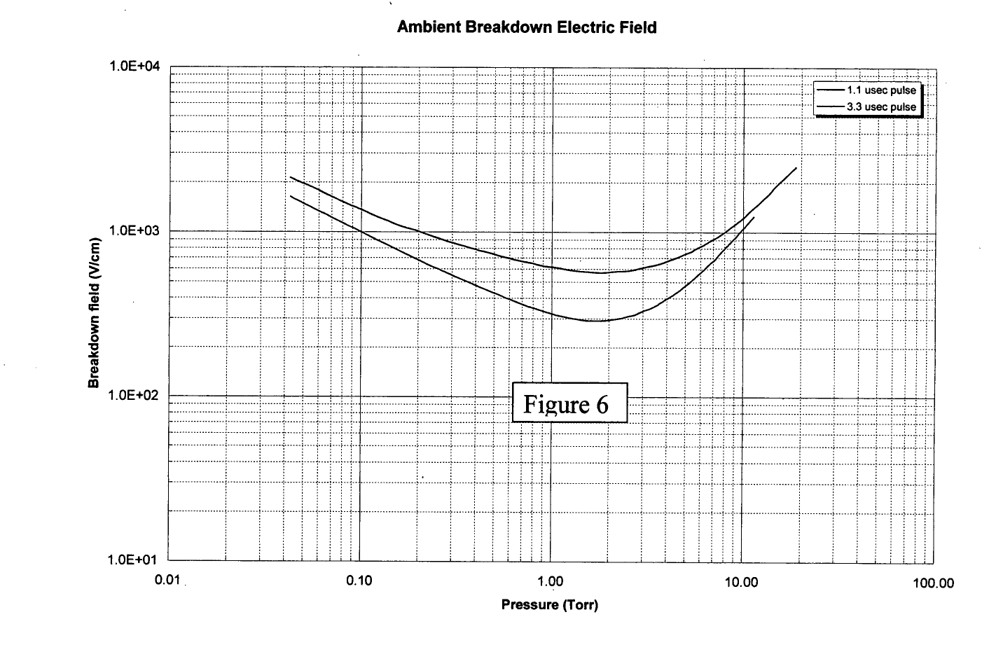

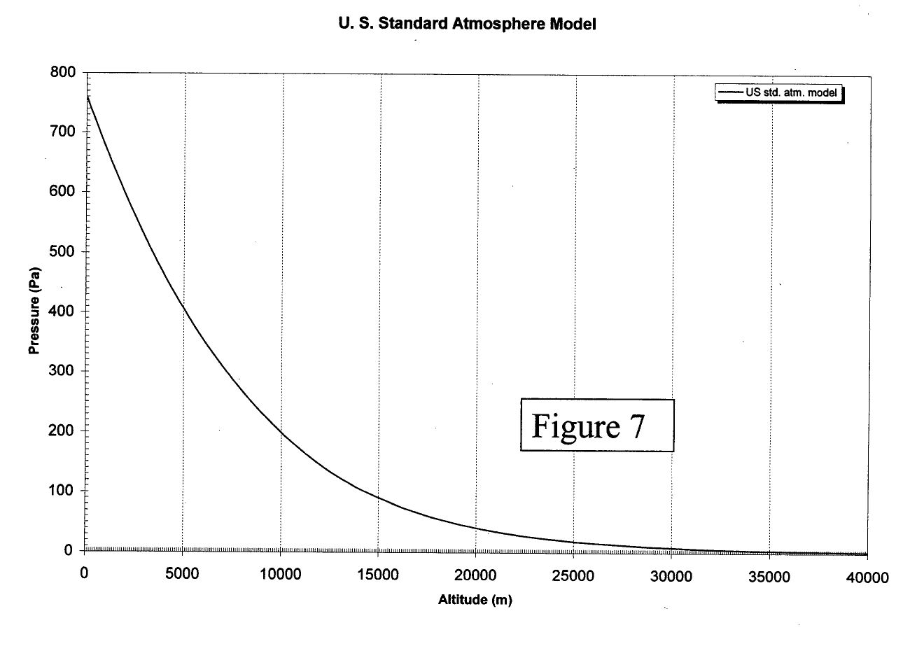

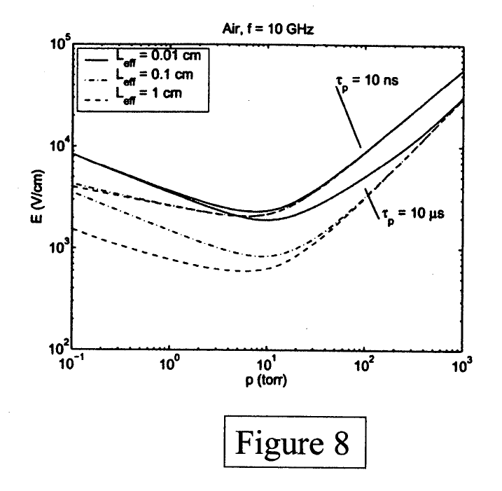

The electrical field strength required for breakdown of ambient air to form a plasma of ionized gas, E_{ambient threshold} has been extensively studied and is a function of applied electromagnetic field pulse length, applied frequency and atmospheric pressure. The value for E_{ambient threshold} in ambient air is shown in FIG. 6 as a function of altitude (Zhang, Thesis, Polytechnic University, 1991). FIG. 6 gives E_{ambient threshold} in units of Volts/cm as a function of pressure in torr. FIG. 7 gives the conversion between torr and height in KM which will be useful in various calculations in this patent document. As can be seen from FIG. 7, the breakdown level is a function of the pulse time τₚᵤₗₛₑ in general, as the value of τₚᵤₗₛₑ decreases E_{ambient threshold} increases. FIG. 8 shows the range of breakdown values from CW (continuous) microwave fields to nanosecond values of τₚᵤₗₛₑ. (Jordon, U, Microwave Breakdown Physics and Applications Thesis, Department of Radio and Space Science, Chalmers University of Technology, Sweden, 2005) An ionization rate equation has been developed which updates these ambient air breakdown papers and the updated rate is described below and the updated equation is used in the computer simulations in this patent document. (Papadopoulos, K. et al, Ionization Rates for Atmospheric and Ionospheric Breakdown, Journal of Geophysical Research, Vol. 98, No. A10, pp 17,593-17,596, Oct. 1, 1993) These values are for “pure” ambient air and can be influenced by particulate matter, humidity and the chemical composition of the atmosphere.

Cosmic Particle Descriptions

Cosmic rays are used in this invention to ignite plasma patterns in the atmosphere below 40,000 meters and micro-meteors are used to ignite plasma patterns above 70,000 meters.

Cosmic Rays-Description

Cosmic rays are charged particles moving nearly at the speed of light illuminating the earth from outer space. Primary cosmic rays are those particles that have traveled through interstellar space and are mostly protons (nuclei of hydrogen atoms), with some alpha particles (helium nuclei), and lesser amounts of nuclei of carbon, nitrogen, oxygen and heavier atoms. These nuclei collide with nuclei in the atmosphere, producing secondary cosmic rays of protons, neutrons, mesons, electrons and gamma rays of high energy, which in turn hit nuclei in the lower atmosphere to produce more particles. The secondary particles shower down through the atmosphere creating copious ionization levels in the atmosphere. (Greider, Cosmic Rays at Earth, Amsterdam Press, 1991.)

Cosmic Rays—Flux in Number of Electrons Per Square Meter Per Second

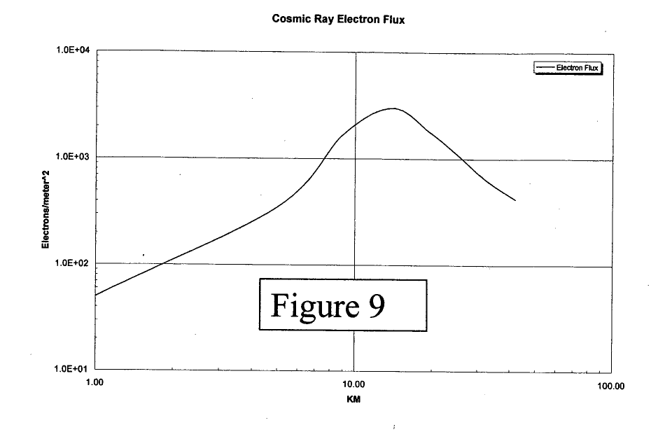

The flux of cosmic ray generated electrons, α_{cosmic ray}, with energy >1 Mev is shown in FIG. 9 (taken from Daniel and Stephens, Cosmic-Ray-Produced Electrons and Gamma Rays in the Atmosphere, Review of Geophysics and Space Physics, Vol. 12, p. 233, May, 1974) The values in this figure is consistent with the comment of Gurevich et al, Physics Letters A 165 (1992) 463-468, in which they describe the flux of cosmic ray secondaries with energy >1 Mev crossing a layer at 10 km altitude as ≈1/cm²-sec. It should be kept in mind that the data has significant scatter, and ignition times calculated using FIG. 9 can vary by one or two orders of magnitude.

Micrometeorites—Description

As the earth orbits the sun, a great number of tiny dust particles enter the earth's atmosphere, they collide with air molecules and leave ionization trails in the form of long, thin parabaloids. These trails of ionized particles reflect radio waves in the low VHF band. A digital communications system that uses these trails (or so called meteor bursts) is called a meteor burst communications system or meteor scatter communication. These trails occur at an altitude of 70-100 KM. An example of such a system is the SNOTEL system, which spans 11 Western States of the U.S. It primarily gathers snow pack and other meteorological data over 600 terminals spread in the valleys of the Rocky Mountains. (Fukada et al, Adv. Polar Upper Atm. Res. 17, 120-136, 2003.)

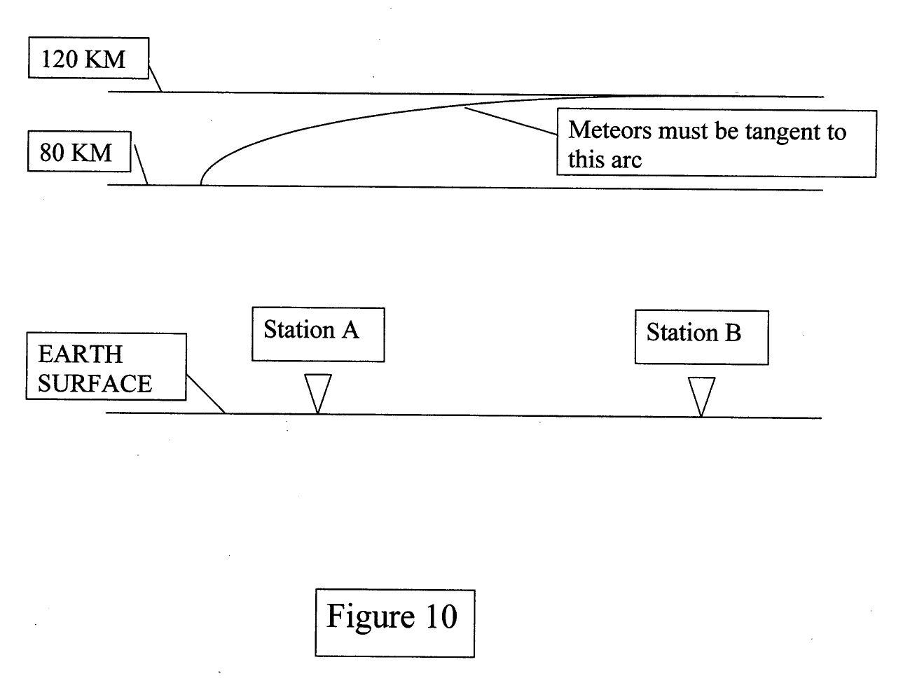

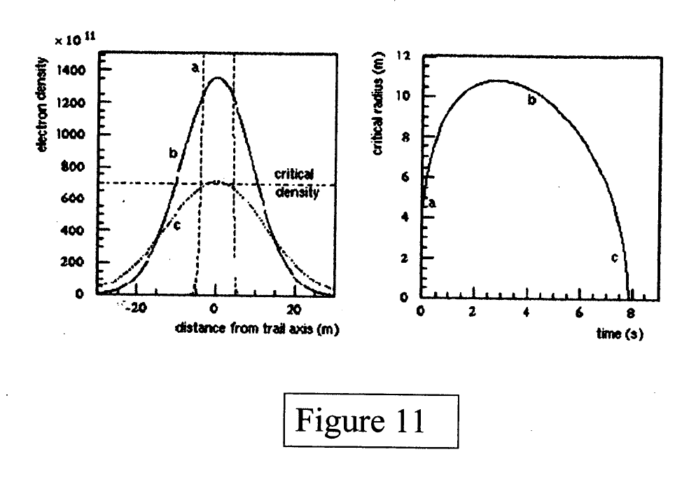

The ionization trails of micro-meteorites are studied with various high powered radars such as the 450 Mhz system at Arecibo. (Janches. D, Observed Diurnal and Seasonal Behavior of the Micro-meteor Flux using the Arecibo and Jicamarca Radars, Cooperative Institute of Research in Environmental Sciences, University of Colorado, Draft, May 26, 2004.) A typical ionization trail trajectory is shown in FIG. 10. (Gorham, P., On Radar Detection of Ultra-High Energy Extensive Air Showers, JPL, RADHEP 2000) The ionization trails are characterized as underdense or overdense depending on the frequency of the electromagnetic wave that is scattered. The electron line densities of such trails are shown in the graph in FIG. 11 (ibid Gorham) Note that the line density per meter can be over 10¹⁴ electrons/meter. When expanded to one square cm, this gives a number density of 10¹² electrons/cm³, which is high enough to reflect signals over 10 Ghz and is more than enough density needed to ignite a plasma layer. The incident meteors have a mass of 0.1 to 10 g. The typical length of the meteor trails ranges from 10 to 15 KM. (Iyono, A. et al, 18^{th} International Cosmic Ray Conference, pp 217-220, Universal Academy Press, Inc., 2003)

Micro-meteors—Flux in Number of Micro-meteors Per Square Meter Per Second

Arecibo has measured the meteor flux at 70,000 to 100,000 meters as about 5-8 meteors per min in a 15 degree angle over the transmitter. This area of detection is about 2×10⁹ meter². This gives a value for the flux of meteors, α_{micrometer} of 10⁻¹⁰ micrometeors/sec-meter². (Janchez, ibid)

Electrical Breakdown by Cosmic Particles

Cosmic Rays

Breakdown by Runaway Electrons in Electrical Storms

The threshold electric field for breakdown in air induced by cosmic-ray-produced multi-Mev electrons is given by the expression:

$${E}_{cosmic critical} ≃ \frac{5.4 * {N}_{atm}}{2.7 * {10}^{19} {cm}^{- 3}} ( KV \text{/} cm ) \qquad ( 1 )$$

This is a value of around 2 KV/cm at sea level. This is compared to the ambient threshold electric field E_{ambient threshold} of ordinary breakdown which is about 23 KV/cm. Gurevich et al, Physics Letters A 165, 463-468, 1992, have suggested and have later shown that cosmic ray runaway electrons are responsible for initiating electrical breakdown in lightening in thunderstorms. (Physics Today, May, 2005) They have studied a particular group of the electrons formed by cosmic rays that can be accelerated to high energies by the electric fields in thunderstorm clouds. In this invention, we propose a method that applies artificial electric field patterns in the atmosphere that can accelerate all the electrons in the cosmic ray electron trails to cause breakdown. Because a greater portion of the electrons are being accelerated, it is expected the electric fields would be still lower than that predicted by equation 1.

Breakdown by Increasing in Electron Number Density in Ionization Trail

The column of high density of electrons along the track of a cosmic ray electron raises the electron number density nₑ and induces a decreases in the breakdown electric field that is proportional to ln

$$ln ( \frac{{n}_{e}}{{n}_{0}} )$$

where n₀ is about 0.01 cm³. (Gurevich, et al, Artificially Ionized Regions in the Atmosphere, Gordon and Breach Science Publishers, 1997) are Typical values for ln

$$( \frac{{n}_{e}}{{n}_{0}} )$$

where nₑ is the column of high density electrons along the track of a cosmic ray electron is typically between 30 and 40. Thus, the value for

$${E}_{cosmic critical} = \frac{{E}_{ambient threshold}}{40} \qquad ( 2 )$$

Which is a significant reduction, and results in a power requirement reduction of a factor of up to 1600. Laboratory experiments validate the dependence on ln

$$( \frac{{n}_{e}}{{n}_{0}} ) .$$

(Kazarin, A. Yu, et al, Sov. J. Plasma Physics 10(6), November-December 1984)
Ignition Time Estimates

The ignition time, τ_{ign} that determines how long the field pattern must be maintained before a cosmic ray electron intersects the field pattern is a function of the probability of a cosmic ray crossing the pattern, α_{cosmic ray} in number/meter²-sec-SR, the Area of the field pattern, A_{field pattern} in meter², the duration of the EM wave pulse τₚ, and the repetition rate fᵣₑₚ as follows:

$${τ}_{ign} = \frac{1}{{α}_{cosmic ray} * {A}_{field pattern} * {f}_{rep} * {τ}_{p}} \qquad ( 3 )$$

For example, at sea level, from FIG. 9 the value of α_{cosmic ray} is about 50 electrons/meter²-sec. If the area of the field pattern, A is 1 meter², the duration of the pulse τₚ is 3 microseconds, the repetition rate fᵣₑₚ is 100 sec⁻¹ then the value of τ_{ign} is 67 seconds. At an altitude of 20 KM, from FIG. 9 the value of α_{cosmic ray} is about 3000 electrons/meter²-sec and the resultant value of τₚ is 1 second. It would not be unreasonable to wait for periods up to hours to accomplish ignition when the large potential power and cost savings are considered. The value of τₚ can range from less than 4 nanoseconds to continuous operation. The repetition rate can be up to 10,000 pulses per second.

Antenna Power Requirements For Electrical Breakdown—Definitions

The above discussion describes values for the electrical field strength required for causing breakdown in air and production of a plasma pattern of ionized gas. The electric field strength of an electromagnetic wave can be related to the power in watts per meter squared by the relationship:

$${P}_{Transmitter} = \frac{{E ( volts \text{/} meter )}^{2}}{377 ( ohms )} ( watts \text{/} {meter}^{2} ) \qquad ( 4 )$$

Where E_{ambient threshold} is in units of Volts/meter².

Using this expression, the power required for ambient breakdown at any altitude can be calculated. For example, in FIG. 6, the minimum in breakdown field of 300 volts/cm occurs at an air pressure of about 2 torr, which is equivalent to about 35 KM altitude. Using equation 4 this gives a value for P_{EM Flux} of about 2×10⁶ watt/meter².

Effective Radiated Power

Specifications of equipment required for air breakdown and creation of artificial ionized plasmas in the air make use of the following definitions:

ERP is the “Effective Radiated Power” and is given by the expression:
ERP=G_{Transmitter}*P_{Transmitter} (watts) (5)

Where G_{Transmitter} is the Gain of the Antenna, which describes its ability to focus at a distance. P_{Transmitter} is the total power in watts radiated by the electromagnetic wave radiator. G_{Transmitter} is given by the expression:

$${G}_{transmitter} = {{π}^{2} ( \frac{{D}_{antenna}}{λ} )}^{2} \qquad ( 6 )$$

Where Dₐₙₜₑₙₙₐ the diameter of the antenna of the electromagnetic wave radiator in meters and λ is the wavelength of the electromagnetic waves in meters. It is illustrative to determine the electromagnetic wave radiator requirements for the example above, in which a P_{EM Flux} of about 2×10⁶ watt/meter² is required at an altitude of 35,000 meters. At a frequency of 3 Ghz the wavelength is 0.1 meters. With Dₐₙₜₑₙₙₐ=500 meters the gain of the transmitters, G_{Transmitter} is 2.4×10⁸. With P_{Transmitter}=1.4×10⁸ watts, the ERP is 3.4×10¹⁶ watts. The nomenclature used to more easily refer to these large units is DBw. DBw is defined as:
DBw=10*log₁₀(ERP) (7)
Thus, to supply a value of P_{EM Flux} of 2×10⁶ watt/meter² at 35000 meters altitude an ERP with a DBw of 165 is required. This is a very large system and is indicative of a high cost.

For comparison purposes, the HAARP facility in Alaska (High Frequency Active Auroral Research Program) is only 86 DBw. That system is reputed to have cost over $200 million. With a value for E_{cosmic critical} up to 1600 times lower than E_{ambient threshold} the required value for ERP becomes 133 which is a much more economical and realistic requirement.

Validation of Air Breakdown by Cosmic-Ray-Produced Multi-Mev Electrons in Electromagnetic Fields

Experimental evidence for cosmic-ray-produced multi-Mev electrons in gases includes cosmic-ray induced lightening phenomena, microwave spark chambers and microwave lamps. Each of these research areas validate the basic assumption of this invention, that if a field pattern is established, breakdown will eventually be induced by a cosmic ray trail intersecting the pattern.

Cosmic-Ray Induced Lightening Phenomena

As discussed above, Gurevich et al, 1992 have suggested and have later shown that cosmic ray runaway electrons are responsible for initiating electrical breakdown in lightening in thunderstorms. (Physics Today, May, 2005) They have studied a particular group of the electrons formed by cosmic rays that can be accelerated to high energies by the electric fields in thunderstorm clouds. They determined that the ambient breakdown electric field in the storm was reduced from 24 Kv/cm to about 2 Kv/cm.

Microwave Cosmic-Ray Spark Chambers

Air breakdown by cosmic-ray-produced primary particles and multi-mev electrons has been experimentally studied in electromagnetic fields in the early days of spark chamber development. Spark chambers are routinely used to determine the trajectories and to identify the tracks of cosmic rays and in particle accelerator experiments. Current technology for particle detection relies on rapidly establishing high DC voltages between arrays of thin plates. However, Lederman (Review of Scientific Instruments, Vol. 32, #5, p. 523, 1961) described experiments on cosmic-ray breakdown in a resonant microwave chamber operating at sea level. The experiments were carried out with 9 Ghz electromagnetic waves in a rectangular cavity operating in the TE₂₀₂ mode. The volume was 7 cc and the gas was argon at up to 3 atmospheres. He determined that the power required for breakdown was about 0.5 kw compared to over 10 KW required for breakdown in the absence of a cosmic ray intersecting the chamber. Subsequent papers by Kustom et al (Nuclear Instruments and Methods, Vol. 118, pp. 203-211, 1974) and by Doviak et al Nuclear Instruments and Methods, Vol. 48, p. 344, 1967 and Nuclear Instruments and Methods, Vol. 54, pp. 161-162, 1967) illustrate the lowering of the electric field intensity required for breakdown microwave field patterns in various gases. FIG. 5 is a photograph of a cosmic ray trail crossing a microwave field pattern. Spark chamber experiments are designed to limit the growth of the discharge in order to obtain well defined images of the tracks. If the duration of the microwave fields applied in the discharge exceeds a few nanoseconds, complete breakdown occurs in the chamber. This is of course, exactly what this present invention requires. i.e. the field pattern region is filled with ionized plasma to form a plasma pattern.

Ignition of Microwave Lamps

Eastlund, in U.S. Pat. Nos. 3,872,349 and 3,911,308 describes the construction and operation of microwave lamps. Ignition of those lamps was dependent on the intersection of a cosmic ray electron with the electric fields in the volume of the lamp. This delay was called the “ignition time” τ_{ign} and could range from a fraction of a second to 2 to 3 minutes. The bulbs were 9 mm in diameter and about 10 inches long. Using equation 3 above, the ignition time is predicted to be about 9 seconds. There is much uncertainty in the value of α_{cosmic ray} therefore the range observed in the microwave lamp experiments is consistent with the cosmic ray flux characteristics.

ERP Values in Ambient Air Determined by Computer Simulation

The basic definitions and discussions of air breakdown phenomena above are presented to define the terms and logic relevant to the process of cosmic ray or meteor trail ignition of breakdown in air. A computer simulation is required to take into account the bulk of the relevant physical phenomena. For example, as the plasma is formed it both reflects and absorbs some of the electromagnetic wave.

The computer simulation used herein assumes a field pattern 104 which is a disc shaped pattern with a radius, r at an altitude of h as illustrated in the schematic drawing in FIG. 1. The underlying equation for growth of a plasma is:

$$\frac{ⅆ {n}_{e}}{ⅆ t} = {v}_{i} {n}_{e} \qquad ( 8 )$$

Where
υᵢ=ionization rate
nₑ=electron number density

The solution of this equation is:
nₑ=n₀e^{υ}^{ᵢ}^{t} (9)
Where n₀=initial electron number density

The simulation is iterative and has inputs of altitude, h, the focusing geometry of the antenna as a function of altitude, and reflection and absorption of the electromagnetic wave from the plasma.

Assuming the breakdown pulse has a duration of τₚᵤₗₛₑ the electron number density nₑ rises from its initial value (typically 0.01 electrons cm⁻³) to a critical density,

$${n}_{e - critical} = \frac{{m}_{e} {ω}^{2}}{4 π {c}^{2}}$$

which is about 10¹¹ cm⁻³ which is the density at which a 3 GHz electromagnetic wave is reflected and the wave no longer penetrates the volume.
n_{e-critical}≦n₀e^{υ}^{ᵢ}^{τ}^{ₚᵤₗₛₑ} (10)
Where c is the velocity of light, and mₑ is the mass of the electron in kg.

It follows that:

$${υ}_{i} \geq \frac{ln ( \frac{{n}_{e - critical}}{{n}_{0}} )}{{τ}_{pulse}} \qquad ( 12 )$$

The simulation used here is based on an expression for υᵢ for altitudes, h>20,000 meters, developed by Papadopoulos et al, Journal of Geophysical Research, Vol. 98, No. A10, pp. 17,593-17,596, Oct. 1, 1993. Note that this paper corrected some errors in the paper by Zhang, 1990 cited above. Their expression for υᵢ is:

And

$${υ}_{i} = [ 1200 ( \frac{ɛ}{eV} ) {ⅇ}^{( - \sqrt{\frac{2 eV}{ɛ}}} ] {υ}_{m} \qquad ( 13 )$$

where ∈=quiver velocity given by

$$ɛ = 0.5 \frac{{ⅇ}^{2} {E}^{2}}{m {ω}^{2}} \qquad ( 14 )$$

and υₘ=6*10⁹ (pressure(torr))sec⁻¹

Imbedded in the simulation are expressions for the reflection and absorption of electromagnetic waves by a plasma which are derived from the dielectric constant of the media which is expressed as:

Complex Permittivity:
∈=∈₀[1−ωₚ²)/(ω²+υₑ²)]−j∈₀[υₑ/ωωₚ²/(ω²+υₑ²)] (15)

Real part of the propagation constant, ξ:

$$\begin{matrix}ξ = \{ \frac{1}{2} [ 1 - {ω}_{p}^{2} \text{/} ( {ω}^{2} + {v}_{e}^{2} ) ] + \\ {{\frac{1}{2} [ {[ 1 - {ω}_{p}^{2} \text{/} ( {ω}^{2} + {v}_{e}^{2} ) ]}^{2} + {[ {v}_{e} \text{/} ω {ω}_{p}^{2} \text{/} ( {ω}^{2} + {v}_{e}^{2} ) ]}^{2} ]}^{\frac{1}{2}} \}}^{\frac{1}{2}}\end{matrix} \qquad ( 16 )$$

Imaginary part of the propagation constant, χ:

$$\begin{matrix}χ = \{ - \frac{1}{2} [ 1 - {ω}_{p}^{2} \text{/} ( {ω}^{2} + {v}_{e}^{2} ) ] + \\ {{\frac{1}{2} [ {[ 1 - {ω}_{p}^{2} \text{/} ( {ω}^{2} + {v}_{e}^{2} ) ]}^{2} + {[ {v}_{e} \text{/} ω {ω}_{p}^{2} \text{/} ( {ω}^{2} + {v}_{e}^{2} ) ]}^{2} ]}^{\frac{1}{2}} \}}^{\frac{1}{2}}\end{matrix} \qquad ( 17 )$$

∈₀=vacuum permittivity
ωₚ=electron plasma frequency
ω=wave frequency
υₑ=electron collision frequency (electron-neutral & electron-electron)
j=imaginary vector

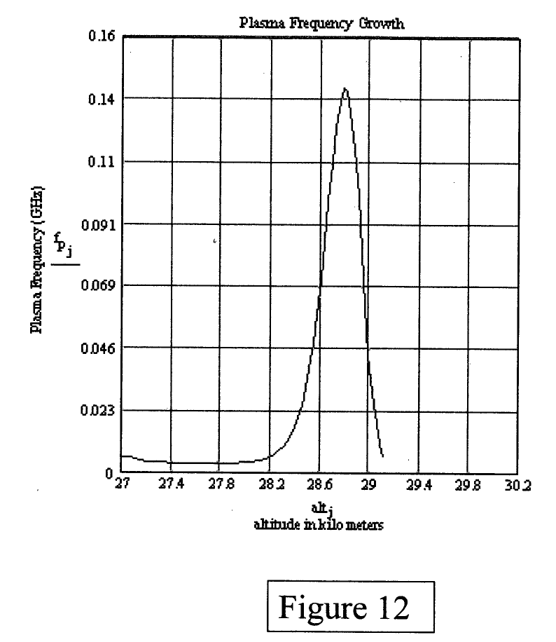

As the simulation progresses the initial plasma layer is very thick. FIG. 12 shows the simulation results for a partially formed plasma by a field pattern generating system 100 with the following parameters:
Generator Power=2.4×10⁸ watts
Dₐₙₜₑₙₙₐ=500 meters
ERP=5.9×10¹⁶ watts
h=30,000 meters
wave frequency ω=3 Ghz
Plasma frequency ωₚ=140 Mhz

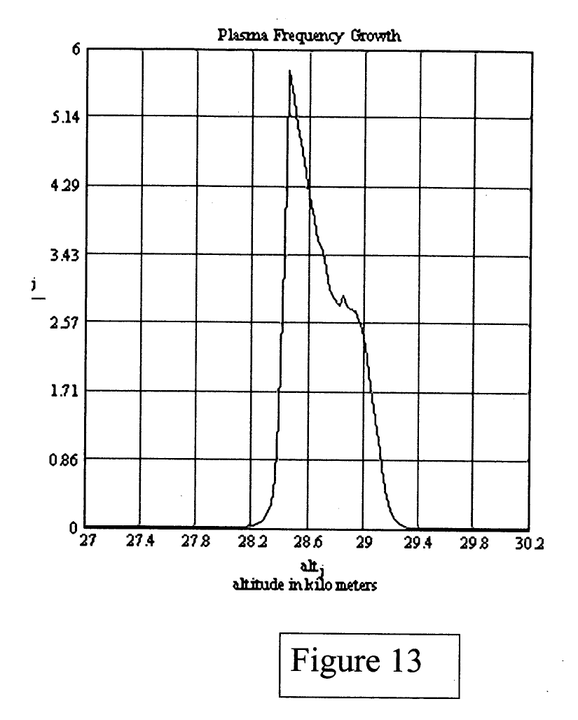

Note that at this partially formed stage of development shown in FIG. 12, the layer is about one km thick, is located at 28.8 km and has a plasma frequency ωₚ of about 140 Mhz that is not high enough to reflect the 3 Ghz electromagnetic waves of the electromagnetic wave generator significantly. At this stage in the simulation, the plasma begins absorbing the electromagnetic waves further increasing the electron number density and thus the plasma frequency ωₚ and a fully formed layer develops. The fully formed layer is shown in FIG. 13. Note that the leading edge, which is the reflecting layer, is at an altitude of 28.5 km. It moves closer to the antenna because of complex absorption processes in the plasma. In this case the layer has a plasma frequency greater than 3 Ghz and completely reflects the 3 Ghz incident wave and is very thin, on the order of a few meters in width.

ERP Values for a Disc Shaped Plasma Pattern

The computer simulation was used to determine the ERP values for formation of a fully developed plasma pattern as a function of altitude as shown in Table 1. The power levels that must be produced by the electromagnetic wave generator above 20,000 meters are on the order of 1-4 megawatts/meter² at altitude. Below 20,000 meters the values are taken from Jordon, ibid and are larger. These very large values of ERP required for breakdown have discouraged construction of such apparatus and experiments have been limited to laboratory situations.

TABLE 1

| Height | Ambient | Ambient Power |
|---|---|---|
| (meters) | ERP | Megawatts/meter2 |
| 1000 | 172 | 1500 |
| 10000 | 171 | 100 |
| 20000 | 158 | 1 |
| 30000 | 164 | 2.3 |
| 40000 | 168 | 3.5 |
| 80000 | 181 | 170 |

Cosmic Particle Ignition Lowers ERP Requirements for Air Breakdown

The values of ERP for electrical breakdown initiated by cosmic particles, cosmic-ray electrons below 40,000 meters and micro-meteors above 80,000 meters are presented in Table 2 for a “best case” of a reduction in power requirements of a factor of 1600. Note that ERP values are in the range of 126 to 151 compared to a range of 158 to 181 for ambient breakdown. The power levels at 30,000 meter altitude are in the 1-2 killowatts/meter² range.

The invention does not necessarily need to be used to reduce the power levels of the generator. Alternatively, the lower ERP values could also be achieved by keeping the power levels high, but utilizing smaller, lower gain antennas-for savings in construction and land use requirements.

TABLE 2

| Height | Cosmic | Cosmic Power | Cosmic |
|---|---|---|---|
| (meters) | ERP | Kilowatts/meter2 | Particle |
| 1000 | 151 | 1060 | Electron |
| 10000 | 139 | 63 | Electron |
| 20000 | 126 | 0.6 | Electron |
| 30000 | 132 | 1.4 | Electron |
| 40000 | 136 | 2.2 | Electron |
| 80000 | 149 | 10.6 | Meteor |

Method for Maintaining the Plasma Pattern After Breakdown

Another principal embodiment of the invention is to maintain the disc shaped plasma pattern 104 in FIG. 1 and/or the crossed beam plasma pattern 303 in FIG. 3 by continuously irradiating the plasma patterns with electromagnetic waves at a power level sufficient to maintain the plasma electron density at the value required by the desired application.

The maintenance power requirements can be a factor from 10 to 100 lower than the value required for electrical breakdown initiated by cosmic particles. Eastlund, in the experimental work leading up to U.S. Pat. No. 3,872,349 generated microwave plasmas in air in sealed quartz chambers. He studied microwave breakdown in the pressure range from 100 to 200 torr, equivalent to an altitude of about 10 km, using a 2450 Ghz source. He found that about 10⁵ watts/meter² would ignite the plasma and about 1000 watts/meter² could maintain the air plasma. Gurevich et al (Gurevich, et al, Artificially Ionized Regions in the Atmosphere, Gordon and Breach Science Publishers, 1997) indicate maintenance power levels up to 10⁵ times less than the ambient breakdown power levels. For example at 40,000 meters with a source with a pulse width τ_{ign} of 10⁻⁹ sec and a power level of 3×10¹¹ watts required for ambient breakdown, but showed that a power level of 1.3×10⁶ watts could maintain the plasma layer with an area of 6000 meter². This 220 watts/meter². Table 3 below presents a summary of the projected maintenance power levels compared to the cosmic ignition power levels.

TABLE 3

| Height | Cosmic | Cosmic Power | Cosmic | Maintenance |
|---|---|---|---|---|
| (meters) | ERP | Kilowatts/meter2 | Particle | Watts/meter2 |
| 1000 | 151 | 1060 | Electron | 5600 |
| 10000 | 139 | 63 | Electron | 560 |
| 20000 | 126 | 0.6 | Electron | 154 |
| 30000 | 132 | 1.4 | Electron | 140 |
| 40000 | 136 | 2.2 | Electron | 220 |
| 80000 | 149 | 10.6 | Meteor | 250 |

Method of Triggering Ignition of Air Breakdown to Produce Artificial Ionized Plasma Patterns in the Atmosphere

The incident flux of cosmic particles is subject to wide variations in time and location because the source flux depends on uncontrolled natural phenomena.

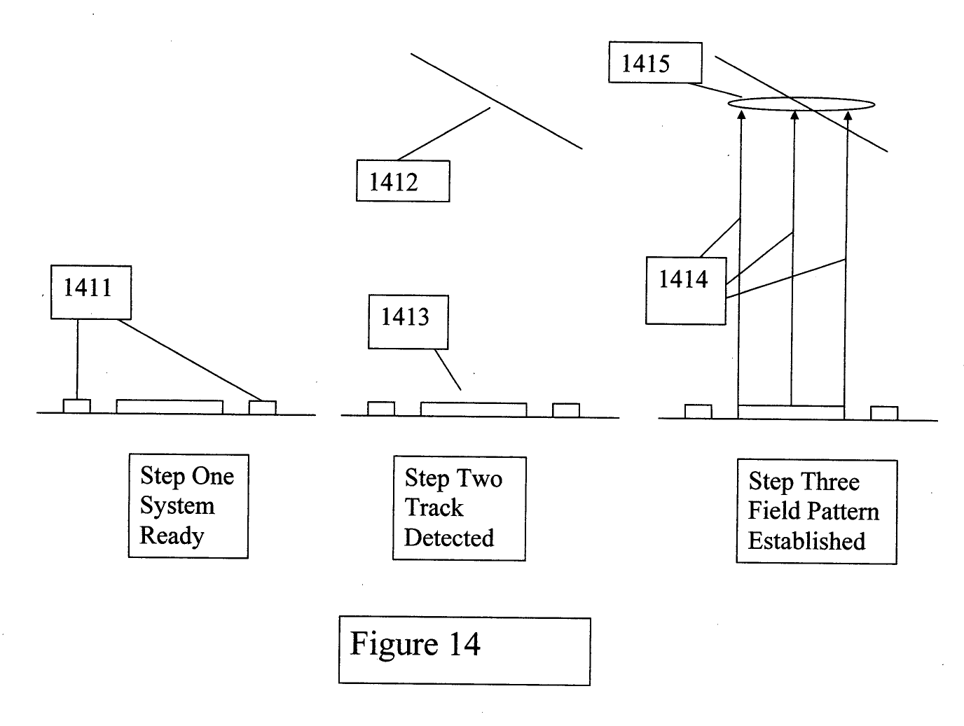

Another principal embodiment of this patent is a method of detecting the cosmic particle track and triggering the electromagnetic wave radiator to apply a field pattern at the location of the track. FIG. 14 is a schematic drawing of three different steps in the triggering sequence. Step one depicts a detector array 1411 and an electromagnetic wave generator 1413. Step two depicts the detector array 1411 detecting the cosmic particle track 1412. The control system feeds the position of the track to the electromagnetic wave generator 1413 that electronically directs the electromagnetic wave radiation to a focus at the cosmic particle track 1412 location. Step 3 is the ignition of a plasma pattern in the electric field pattern 1412 by the electromagnetic wave radiation from the electromagnetic wave radiator 1412. The detector response time can be on the order of one or more nanoseconds. The time to determine the position of the ionization trail can range from a microsecond to about 2 milliseconds.

Cosmic Ray Electron Detectors

The detector array 1411 for cosmic rays electrons can be constructed with Geiger-Muller detectors for detecting the muons generated by cosmic rays. Cerenkov detectors which detect photons can also be used. The response time of a Geiger-Muller detector can be in the nanosecond range and the targeting system which determines the position of the cosmic ray electron shower or trail can be on the order of a microsecond. The electromagnetic wave radiator 1413 can be turned on in less than a microsecond, making it possible to apply the field pattern to the region of the track while the electron density in the track is still high. The time to acquire the pattern and compute the location of the track could be longer than one microsecond and will be a function of the altitude of the ionization trail.

Meteor Trail Detection

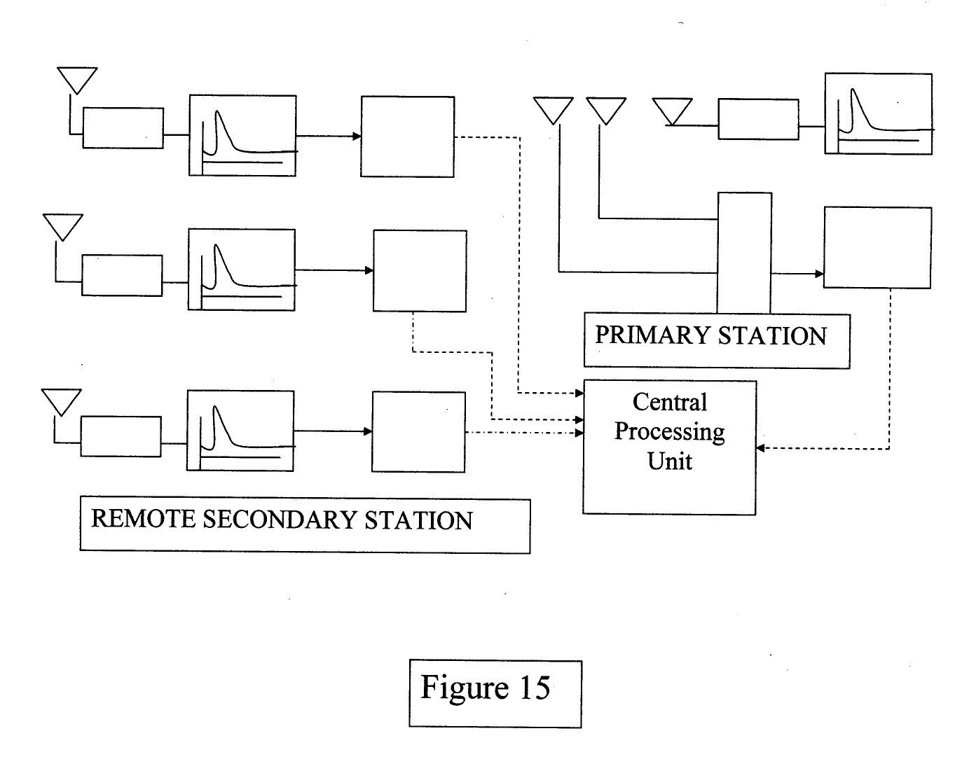

The detector array 1411 for meteor trails can be vhf radar transmitters. FIG. 15 is a schematic drawing of a meteor trail position detector array. The response time of the vhf radar waves can be less than a microsecond and the position information can be developed in a time between one microsecond and 10 milliseconds. The electromagnetic wave radiator 1413 can be turned on in less than a microsecond, making it possible to apply the field pattern to the region of the track while the electron density in the track is high.

Method of Reconfiguring the Shape of a plasma Pattern Established by Ignition with Cosmic Particles

The initial size of the plasma pattern is determined by the need for the electromagnetic wave generator to establish an electric field pattern with a peak intensity equal to E_{cosmic critical}. The plasma pattern can be maintained as described above.

Another principal method of this patent is to change the size or shape of the plasma pattern after it is established by modifying the electric field pattern. This can be done on a stationary or a dynamic basis. An example of a stationary basis method would be to change the focal pattern of the electromagnetic wave generator. An example of changing on a dynamic basis would be to change the focal position of the antenna by changing the frequency and the phase of the electromagnetic radiation generated by each radiating element of the array. U.S. Pat. No. 5,041,834 by Koert describes such a technique for tilting a plane artificial ionospheric mirror radar reflector.

Method of Changing the Physical Properties of a plasma Pattern established by Ignition with Cosmic Particles

Applications of plasma patterns established by ignition with cosmic particles include applications based on reflecting electromagnetic radiation from the patterns such as telecommunications, conducting electrical energy via the electrical conductivity of the layer in lightening control, or absorbing electromagnetic radiation to provide localized heating of the atmosphere in weather modification.

Another principal method of this patent is to increase the reflectivity and electrical conductivity of the plasma pattern by increasing the ERP value of the electromagnetic wave radiator when needed by an application after formation of the plasma pattern with an initial ERP value.

Another principal method of this patent is to heat the air in the pattern by directing electromagnetic wave radiation at the pattern at a frequency that absorbs in a desired distance in the air. This frequency is typically greater than the electromagnetic wave frequency forming the pattern because frequencies below the formation frequency are reflected efficiently from the pattern and can't be used to heat it.

Communications Applications

Cell Phone Service Enhancement

Communication within cell phone areas can be hampered by absorption of the communication signals by buildings or hills and mountains. Siteing of cell phone towers to work around such obstacles can be expensive.

Another principal embodiment of this invention is the creation of a disc shaped plasma pattern at an altitude of at least 10,000 meters over one or more existing cellular communication towers. The function is to provide an all air path for linking individual cell phone signals to at least one cell phone tower.

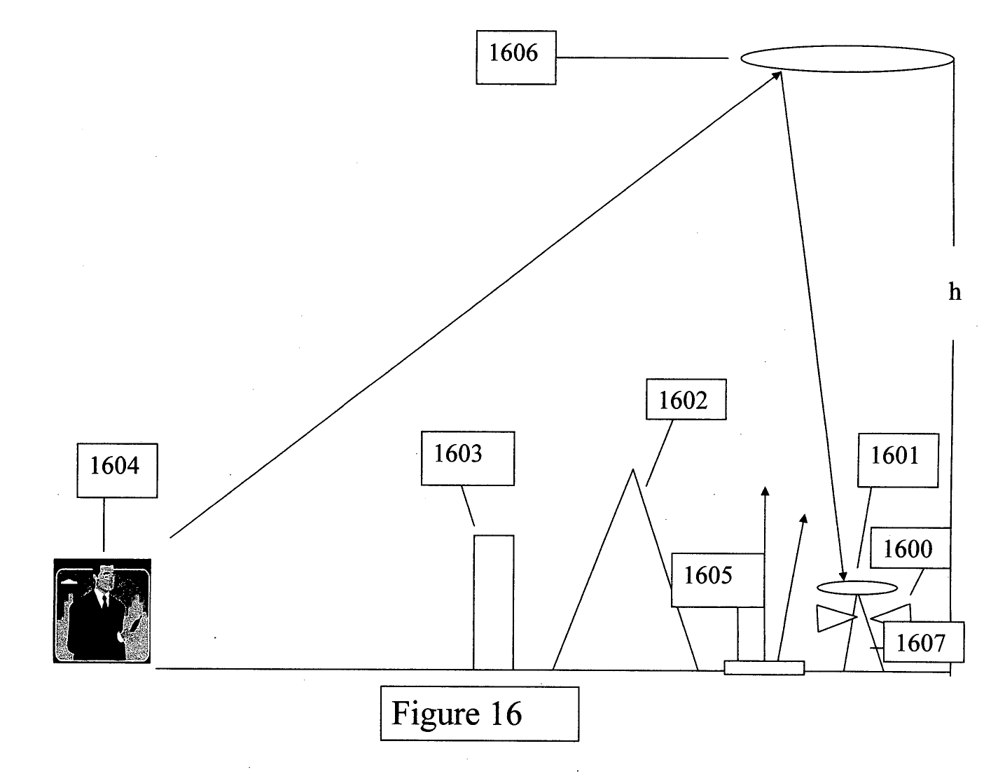

FIG. 16 is a schematic drawing of a cell phone communications area. The cell phone communications system under present operation includes a tower base station 1607 which supports a cell phone base station antenna 1600. Buildings 1603 and mountains 1602 can be between the tower and the cell phone user 1604. These obstacles can degrade or eliminate the signal, leading to dropped signals. The industry designs its cell phone geometry and situation to have a maximum signal loss of −120 dB, based on a cell phone with a power of 1 watt at 900 Mhz. The signal is blocked when the obstacles increase the signal loss and no readable signal is received.

In this application, a plasma pattern 1606 is created via the cosmic ignition method at an altitude of 10,000 meters, and an upward pointing antenna 1601 is placed on the top of the antenna 1607 on top of the base station 1600. An alternate path is now established between the cell phone user 1604 and the upward pointing antenna 1601. The plasma pattern 1606 is as a low power virtual mirror that reflects the tele-communications signals with high fidelity. The plasma pattern 1606 can support CDMA, GSM, TACS, SMR,IMT2000 (3G) and all other cellular communications signals. The apparatus described herein provides a plasma pattern that gives a −100 dB maximum loss between the cell phone and the cell tower with no blockage by hills or buildings. This is a large advantage over present systems.

The electromagnetic wave radiator apparatus 1605 used to produce and maintain the plasma pattern for a 10,000 meter altitude is designed to supply an ERP of 139 dB (See Table 2). The electromagnetic wave radiator can be a phased array with multiple active radiating elements that focus the electromagnetic waves in a disc shaped pattern at an altitude of about 10,000 meters, in a disc shaped pattern. Each radiating element has its individual phase and frequency controlled by a control module. The radiating element is assumed herein to be a 1 meter diameter parabolic dish. Other radiating element geometries such as dipoles, slots, log-periodic antennas or horns could be used.

The electromagnetic wave source for each radiating element is assumed to be a magnetron operating at about 3 Ghz. It could also be a klystron, gyrotron or other microwave generator. The ability to produce a plasma pattern at 10,000 meters with a magnetron based system is a unique new concept, as all previous suggestions by Koert, U.S. Pat. No. 5,041,834 and Vikharev, American Geophysical Union, 1994 required microwave generators with capabilities of billions of watts.

With the cosmic particle ignition method, ignition of a disc shaped pattern with a focal area of 4-5 meters² requires about 500,000 watts. A restaurant style microwave oven magnetron operates at 2.5 Ghz and can produce 5,000 watts. This electromagnetic wave radiator of this invention would use 100 such magnetrons in a “thinned array” distributed over a 400 meter diameter area. The array 1605 is depicted schematically in FIG. 16. Individual elements can be located on rooftops or other structures with line of sight to the focal pattern 1606.

The flux of cosmic ray electrons at about 10,000 meters is indicated to be about 1300/sec-meter² as shown in FIG. 9. This gives an ignition time τ_{ign}, of less than a millisecond. After ignition, the power level of the phased array can be reduced to about 50,000 watts for maintenance of the plasma pattern which would allow the plasma pattern to operate in a continuous fashion with an area of about 100 meter². (See Table 3) The components of the electromagnetic wave radiator are highly reliable with magnetron lifetimes in excess of 10,000 hours. The power can be supplied by a power grid or with a 50,000 watt generator. Peak power of 500,000 watts for ignition of the plasma pattern can be provided with capacitor or battery energy storage.

The power levels in Tables II and III for cosmic particle ignition of plasma patterns can vary by an order of magnitude or more. For example, particulates, chemicals of water droplets in the air could lower the electrical breakdown field. If the electron number density in the ionization trail is too low, the electrical breakdown field would be higher. Thus, the power level required for ignition of a plasma pattern for cellular communication could range from 50,000 watts to 5,000,000 watts. The highest power could be supplied by 1,000 radiating elements using restaurant microwave oven magnetrons, such as the Hitachi M131. Increasing the frequency of the electromagnetic radiation would increase the power required. This can be seen in equation 13 at the ionization rate decreases with increasing frequency. However, practical systems of this method would be possible using electromagnetic wave frequencies from 900 Mhz to 25 Ghz. (At about 25 Ghz, rain could absorb the power and diminish practicality.) The source can be pulsed or CW.

Environmental and Safety Advantages

Use of distributed restaurant style microwave oven sources has safety advantages. An airplane could safely fly through the pattern in 0.01 second. The skin of the airplane reflects the waves, but even if it absorbed the waves, the total energy deposited in the plane would be less than 1000 joules, about the energy in a jelly doughnut. However, this could extinguish the plasma. The plasma could be reignited quickly.

In the event of clouds or thunderstorms, the focal region would include water droplets and vapor.

The water droplets can attach electrons, which would decrease the electron number density in the plasma. However, they also would reduce the electrical breakdown field required and the effects would probably balance out. Eastlund has used sprays of water droplets to create visible air plasmas around oil field equipment operating at high voltages.

Short Haul Cellular System

nother principal embodiment of this patent is a short haul cellular communications system.

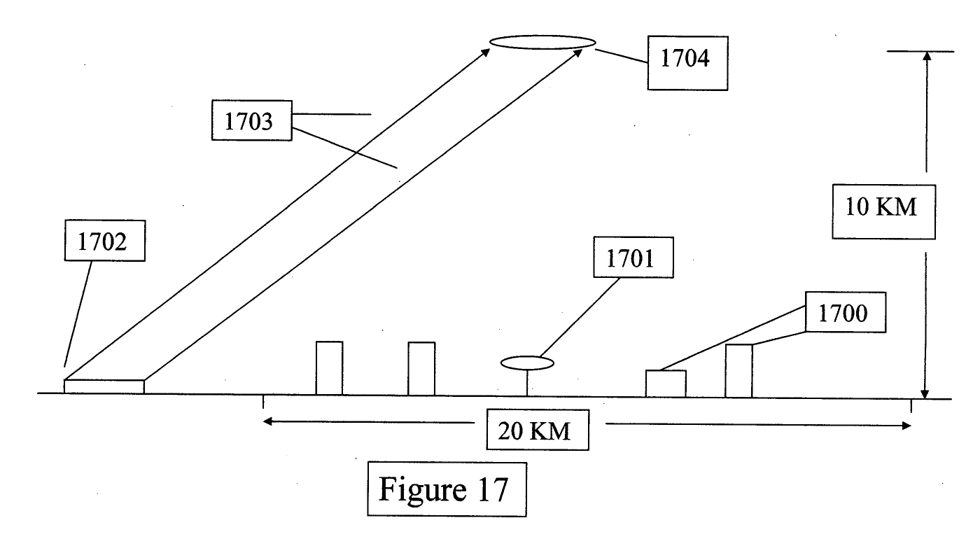

A complete cellular system covering a 20 KM diameter area could be provided with one plasma pattern reflector at an altitude of about 10,000 meters. A schematic drawing of such a system is shown in FIG. 17. A plasma pattern 1704 is created at an altitude of about 10,000 meters with an electromagnetic wave radiator 1702 that is located on the edge of the 20 KM diameter area and beams its electromagnetic radiation 1703 to the focal region at 1704. The electromagnetic wave radiator 1702 could alternatively be located within the area. A single base station 1701 would receive signals from cell phones located throughout the area and broadcast signals to those cell phone by reflection off the plasma pattern 1704. Buildings 1700 in the area would not block the cellular signals as in a conventional cellular system. FIG. 17 depicts a plasma pattern produced by a single electromagnetic wave radiator. Two or more electromagnetic wave radiators could also be used and the plasma pattern could be similar to the pattern depicted in FIG. 3, which occurs with crossed beams.

With the cosmic particle ignition method, ignition of a disc shaped pattern with a focal area of 4-5 meters² requires about 500,000 watts. A restaurant style microwave oven magnetron operates at 2.5 Ghz and can produce 5,000 watts. This electromagnetic wave radiator of this invention would use 100 such magnetrons in a “thinned array” distributed over a 400 meter diameter area.

The flux of cosmic ray electrons is indicated to be about 1300/sec-meter² as shown in FIG. 9. This value gives an ignition time τ_{ign} of less than a millisecond. After ignition, the power level of the phased array can be reduced to about 50,000 watts for maintenance of the plasma pattern which would allow the plasma pattern to operate in a continuous fashion with an area of about 100 meter². The system would be designed to have a maximum loss between cell phones and the base station of less than −120 dB. The power levels in Tables II and III for cosmic particle ignition of plasma patterns can vary by an order of magnitude or more. For example, particulates, chemicals of water droplets in the air could lower the electrical breakdown field. If the electron number density in the ionization trail is too low, the electrical breakdown field would be higher. Thus, the power level required for ignition of a plasma pattern for cellular communication could range from 50,000 watts to 5,000,000 watts. The highest power could be supplied by 1,000 radiating elements using restaurant microwave oven magnetrons, such as the Hitachi M131. Increasing the frequency of the electromagnetic radiation would increase the power required. This can be seen in equation 13 at the ionization rate decreases with increasing frequency. However, practical systems of this method would be possible using electromagnetic wave frequencies from 900 Mhz to 25 Ghz. (At about 25 Ghz, rain could absorb the power and diminish practicality.) The source can be pulsed or CW. The system could be operated at with plasma patterns at altitudes from 10,000 to 30,000 meters.

City Wide Cellular System

Another principal embodiment of this patent is a city wide cellular system. A city wide cellular system covering a city of 60 KM diameter can be operated with a plasma pattern established at 30 KM. This is also energetically the most efficient altitude for generation of the plasma layer.

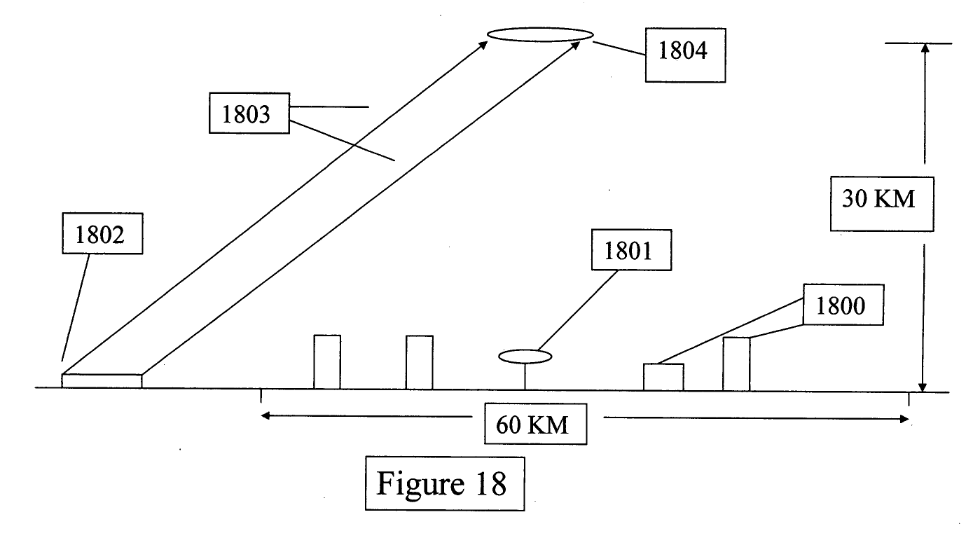

A schematic drawing of such a system is shown in FIG. 18. A plasma pattern 1804 is created at an altitude of about 30,000 meters with an electromagnetic wave radiator 1802 that is located on the edge of the 60 KM diameter area and beams its electromagnetic radiation 1803 to the focal region at 1804. The electromagnetic wave radiator 1802 could alternatively be located within the area. A single base station 1801 would receive signals from cell phones located throughout the area and broadcast signals to those cell phone by reflection off the plasma pattern 1804. Buildings 1800 in the area would not block the cellular signals as in a conventional cellular system. FIG. 18 depicts a plasma pattern produced by a single electromagnetic wave radiator. Two or more electromagnetic wave radiators could also be used and the plasma pattern could be similar to the pattern depicted in FIG. 3, which occurs with crossed beams.

With the cosmic particle ignition method, ignition of a disc shaped pattern with a focal area of about 2000 meters requires about 5,600,000 watts. The ERP of the system would be 132 dew. A restaurant style microwave oven magnetron operates at 2.5 Ghz and can produce 5,000 watts. This electromagnetic wave radiator of this invention could use 1000 such magnetrons in a “thinned array” distributed over a 200 meter diameter area. Alternately, Klystrons similar to those at SLAC could be used. There are 1.3 MW Klystrons that operate continuously one of these could be used with a single large parabolic antenna. One version of a SLAC klystron produces 75 MW and operates in the 10 Ghz range. The lifetime of these klystrons are in the 10,000 hour range and would be suitable for large city wide cellular system construction.

The flux of cosmic ray electrons is indicated to be about 1300/sec-meter² as shown in FIG. 9. This gives an ignition time τ_{ign} at an altitude of about 10,000 meters of less than a millisecond. After ignition, the power level of the phased array can be reduced to about 560,000 watts for maintenance of the plasma pattern which would allow the plasma pattern to operate in a continuous fashion with an area of about 4000 meter². This large area reflector would result in a cell phone system with less than −120 dB losses over its whole coverage area.

The power levels in Tables II and III for cosmic particle ignition of plasma patterns can vary by an order of magnitude or more. For example, particulates, chemicals of water droplets in the air could lower the electrical breakdown field. If the electron number density in the ionization trail is too low, the electrical breakdown field would be higher. Thus, the power level required for ignition of a plasma pattern for cellular communication could range from 500,000 watts to 50,000,000 watts. The highest power could be supplied by 10,000 radiating elements using restaurant microwave oven magnetrons, such as the Hitachi M131. Increasing the frequency of the electromagnetic radiation would increase the power required. This can be seen in equation 13 at the ionization rate decreases with increasing frequency. However, practical systems of this method would be possible using electromagnetic wave frequencies from 900 Mhz to 25 Ghz. (At about 25 Ghz, rain could absorb the power and diminish practicality.) The source can be pulsed or CW. The plasma pattern of this system could be established at altitudes between 30,000 and 40,000 meters.

Five Plasma Pattern Reflector for High Signal Strength

The dB ratings for the applications discussed above were calculated using a conventional radar equation for scattering off a plane reflector. Additional gain of the system can be obtained if the plasma pattern is shaped in a roughly parabolic shape.

Another principal embodiment of this patent is to make an approximately parabolic shape using five separate plasma patterns generated with the power level described above for a city wide cellular system. This system would provide a 20,000 meter² reflecting surface. The surface itself will provide additional gain for the communications signals because it concentrates the cell phone signal on the location of the base station.

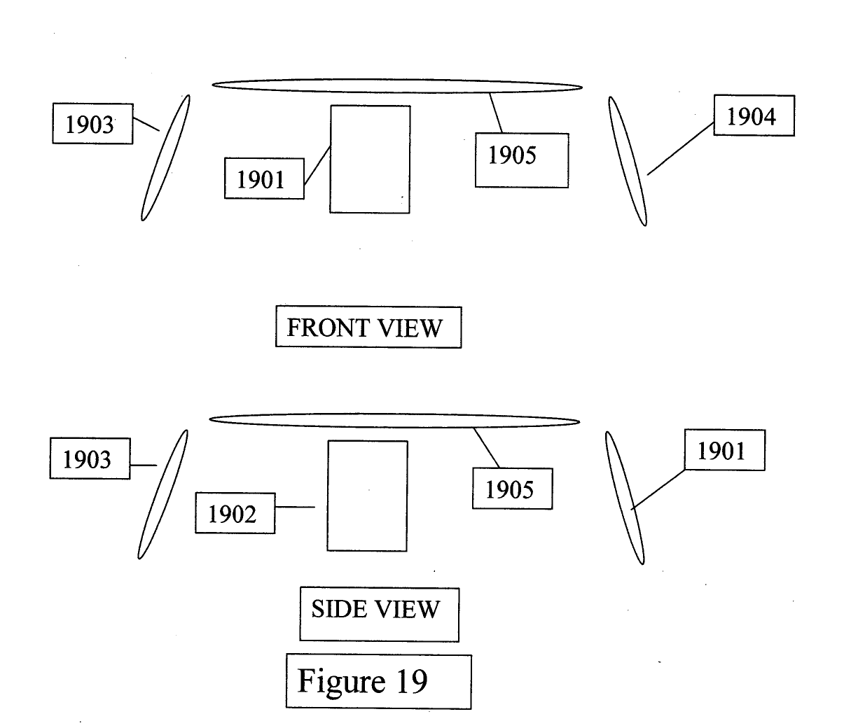

FIG. 19 is a schematic drawing of such a five panel system. A side view and a front view are depicted. The top panel 1905 is the same as plasma pattern 1804 in FIG. 18. The side panels 1901, 1902, 1903 and 1904 are like plasma pattern 1804 but tilted at an angle with respect to the horizontal. The properties and apparatus required to produce each of the five panels is roughly the same as that of the city wide system described above.

The additional gain in signal strength with this system could make it possible to provide very high data rates to cellular equipment, possibly giving a WI FI connection to the whole city.

Long Haul Communications System

Long haul communication is presently primarily accomplished with microwave relays, copper wires, optical fiber or satellites. Another principal embodiment of this invention is to erect shaped plasma patterns at two different locations above the earth's surface, each pattern located at an altitude of 80,000 meters and to use a base station at each location to send and transmit telecommunications data.

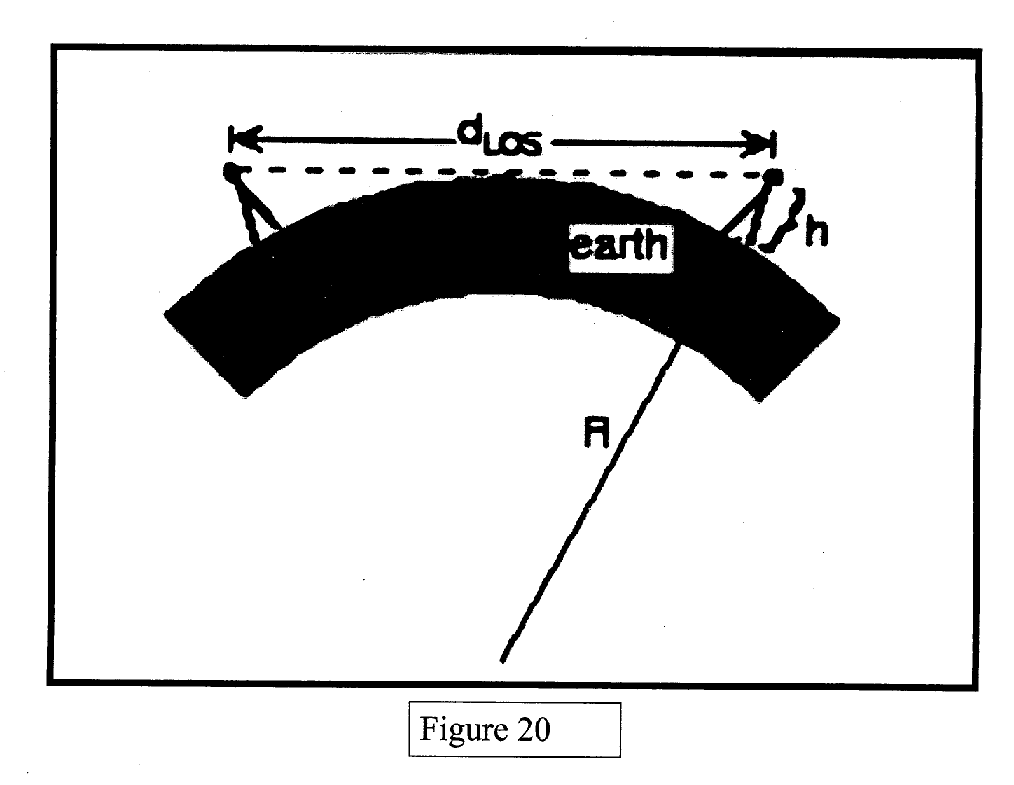

FIG. 20 is a schematic of two antennas at the same height, h separated by a distance dₗₒₛ. The maximum line of sight distance is that which just grazes the earth's surface. The radius of the earth is 6.38×10³ KM. For reflectors located at h=80,000 meters, the value of dₗₒₛ is about 1600 KM.

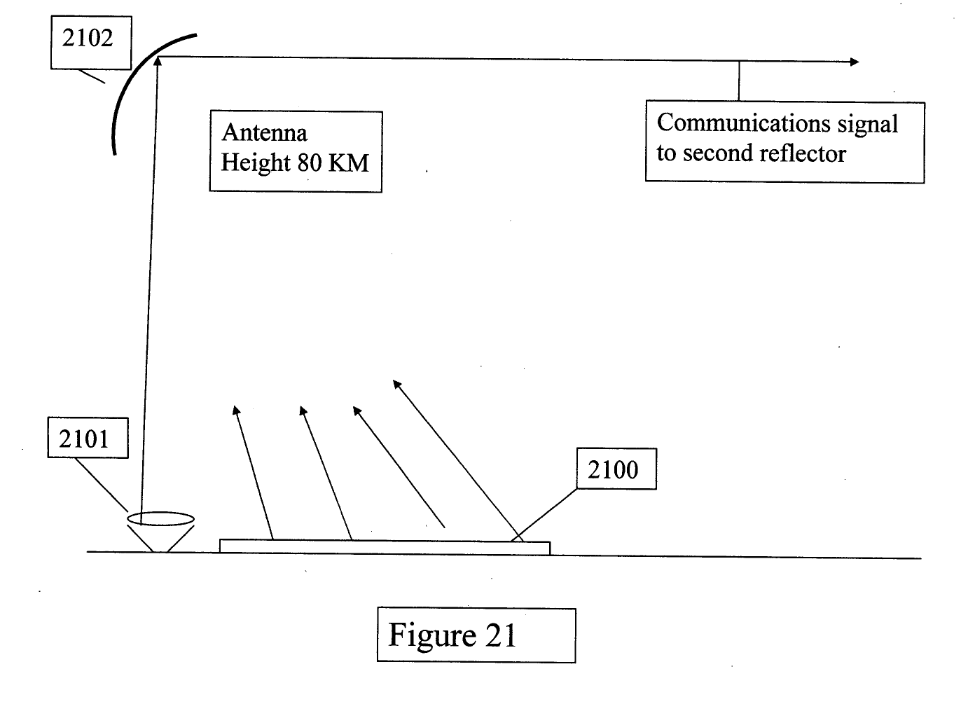

FIG. 21 is a schematic drawing of one such antenna located at 80,000 meters above the earth's surface. It is drawn in a dual paraboloid shape, A dual paraboloid has been found to be ideal for imaging lamps and should allow very high gain from a long haul reflector. (Li, Kenneth, Etendue Efficient Coupling of Light using Dual Paraboloid Reflector for Projection Display”, SPIE, Projection Display, January 2002). The electromagnetic wave radiator 2100 is a phased array that can vary frequency and phasing to produce the double paraboloid shaped field pattern 2102. The communications signals are beamed to the paraboloid shaped field pattern 2102 from a communications system 2101.

At an altitude of 80,000 meters, the ERP required for making the plasma pattern is 149 dBw. Cosmic ignition of the plasma pattern will require an apparatus in which the electromagnetic wave radiator operates at a frequency of about 3 Ghz and has 5 Megawatts of power and the phased array has a diameter of 415 meters. Maintenance operating of the plasma pattern will require about 500,000 watts to support a pattern that has an area of 2,000 meters².

The value for the ignition time of the pattern, τ_{ign} based on the frequency of micro-meteor trails of α_{micrometeor}=10⁻¹⁰ micrometeors/sec-meter² is about 1000 hours for a field pattern of 2,000 meter². The statistical nature of meteor-trail occurrence and this large value for τ_{ign} makes the triggered mode of operation of the invention the preferred mode, as within the range of the phased array antenna, 5 to 8 micro-meteors are detected per minute. The power levels in Tables II and III for cosmic particle ignition of plasma patterns can vary by an order of magnitude or more. For example, particulates, chemicals of water droplets in the air could lower the electrical breakdown field. If the electron number density in the ionization trail is too low, the electrical breakdown field would be higher. Thus, the power level required for ignition of a plasma pattern for cellular communication could range from 500,000 watts to 50,000,000 watts. The highest power could be supplied by 10,000 radiating elements using restaurant microwave oven magnetrons, such as the Hitachi M131. Increasing the frequency of the electromagnetic radiation would increase the power required. This can be seen in equation 13 at the ionization rate decreases with increasing frequency. However, practical systems of this method would be possible using electromagnetic wave frequencies from 900 Mhz to 25 Ghz. (At about 25 Ghz, rain could absorb the power and diminish practicality.) The source can be pulsed or CW.

Weather Control Applications

The average energy turnover in storm systems can range from 7×10⁹ watts in small thunderstorms to 7×10¹⁴ watts in a hurricane. In the mid 1980's, antennas producing up to 10¹² watts were studied by ARCO and the U.S. Department of Defense for military applications in the ionosphere. Because of the similarity between the proposed antenna power and the energy turnover of some typical storm systems, applications for weather modification in the troposphere were proposed. See U.S. Pat. Nos. 4,712,155, 4,686,605 and 5,038,664. The HAARP (High Frequency Active Auroral Research Program) antenna built by the Department of Defense in Alaska is to shortly be operating at a power level of 3.6×10⁶ watts, which is adequate for major modifications of the ionosphere. A paper published by HAARP researchers that can be linked to weather research is Sofko et al, “SuperDarn observations of medium-scale gravity wave pairs generated by Joule Heating in the Auroral zone” Geophysical Research Letters 24(4), 485-588, 2000. Gravity Waves have been shown to influence the Jet Stream by Sullivan et al, “Generation of Intertia-Gravity Waves in a Simulated Life Cycle of Baroclinic Instability, Journal of the Atmospheric Sciences, p. 3695, Nov. 1, 1995. The HAARP antenna operates between 2 and 10 Megahertz, which is a frequency range without interactions in the atmosphere. See Conference Proceedings of the AGARD NATO Conference No. 485 on Ionospheric Modification and its Potential to Enhance or Degrade the Performance of Military Systems, 1990. According to the NATO paper, the only interactions with the atmosphere are above 26 Ghz for absorption by water droplets and above 90 Ghz for absorption by molecules such as CO².

In 1998, Eastlund studied the use of microwave radiation of 26 Ghz to 36 Ghz to heat water droplets in the cold rainy downdraft of a mesocyclone to mitigate tornadogenesis. See the “Workshop on Space Exploration and Resources Exploitation-Explospace, Oct. 20-22, 1998, Sardinia, Italy. The difficulties in targeting a cold rainy downdraft in a mesocyclone were highlighted in “Mesocyclone Diagnostic Requirements for the Thunderstorm Solar Power Satellite Concept”, Proceedings of the Second Conference on the Applications of Remote Sensing and GIS for Disaster Management, Jan. 19021, 1991, GWU, Sponsored by NASA and FEMA. The numerical model ARPS (Advanced Regional Prediction System) at the Center for Analysis and Prediction of Storms (CAPS) at the University of Oklahoma was used to study microwave heating of cold rainy downdrafts. The computational limitations required deposition of energy in very large volumes, but the results did indicate the possibility of tornado mitigation.

The ARPS code initiates the mesocyclone development sequence by assuming a 10 degree K temperature rise over a disc shaped diameter of about 10 KM and uses the wind patterns recorded by balloon born sensors as an input parameter. Recent simulations by Ming Xue, (See, Tornadogenesis within a Simulated Supercell Storm, 22^{nd} Severe Local Storms Conference, Oct. 6, 2004 further develop the computational capabilities of the code.

Other approaches to weather mitigation utilize various technological options, such as airborne cloud seeding or covering the surface of the ocean with chemicals.

This invention of cosmic ignition of plasma patterns in the air includes two new approaches to weather modification.

Another principal embodiment of this invention is to use the method of cosmic particle ignition to create plasma patterns in the air and to use the plasma pattern as a heating element to deposit energy in the air in localized regions and generate acoustic waves or gravity waves that can influence wind speed and direction.

Another principal embodiment of this invention is to use the method of cosmic particle ignition to create plasma patterns in the air and to use the plasma pattern as a means of locally changing the electrical conductivity of the air in specific regions of a weather pattern and manipulate the electrical forces in the weather pattern.

Air Heating to Generate Atmospheric Wave Phenomena

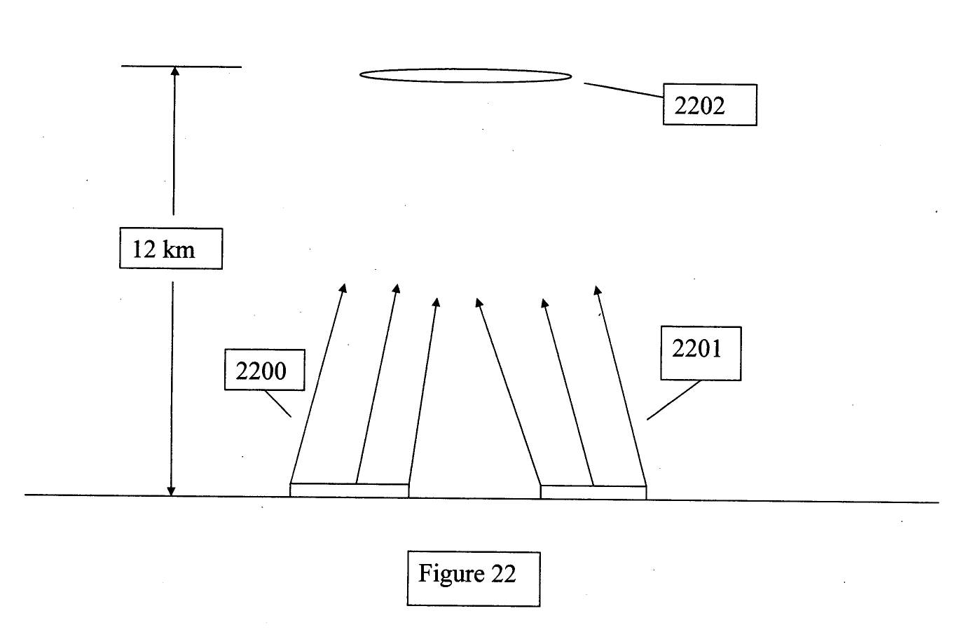

The method of deposition of energy in the air is illustrated in FIG. 22. FIG. 22 is a schematic drawing of a plasma pattern 2202 created at an altitude of about 12 KM with a first electromagnetic wave radiator 2200. A second electromagnetic radiator 2201 directs electromagnetic waves at the plasma pattern 2202 and deposits energy in the pattern.

The change in temperature of a volume of air is a function of the pressure in torr, the specific heat of air (0.7165 kilojoules/kilograms-° K at atmospheric pressure) and the amount of electromagnetic energy absorbed per cubic meter. The absorption of the electromagnetic heating wave in the plasma pattern can be determined as follows (in dB):

$$dB ( absorption ) = 10 * {log}^{\frac{2 χd}{c}} \qquad ( 18 )$$

Where χ is found in equation 17. It is a function of the frequency of the heater wave, the electron number density of the plasma pattern and the collision frequency of the electrons with the air. The thickness of the plasma pattern is d. In general, as the frequency of the heater wave becomes greater than the frequency of the electromagnetic wave maintaining the plasma pattern, the value of d increases. i.e. the layer is thicker.

As an example, if the 2.5 Ghz first electromagnetic wave radiator 2200 used for establishing the plasma pattern at an altitude of 10,000 meters, such as the plasma pattern created for the short haul cellular system, then the 50,000 watt maintenance beam would be absorbed in a plasma pattern thickness d of about 3 meters and the heating rate of the air would be about 5° K in 16 seconds. If the second electromagnetic wave radiator 2201 is a 5 Ghz wave and the applied microwave heating power is 1500 watts/meter² the heating rate over a 6 meter depth, the heating rate would be 5° K in 7 seconds. This height is similar to that of the tropospheric jet stream at about 12,000 meters. Sullivan ibid describes 10° K temperature variations in gravitational waves. Thus, this heating method can quickly supply temperature rises in the air that are consistent with those natural wave systems that influence atmospheric weather.

This method can be used to heat in patterns than are thin or thick and the plasma patterns can be like those used for the communications applications or they can be tailored to deposit energy in specific regions of a weather pattern.

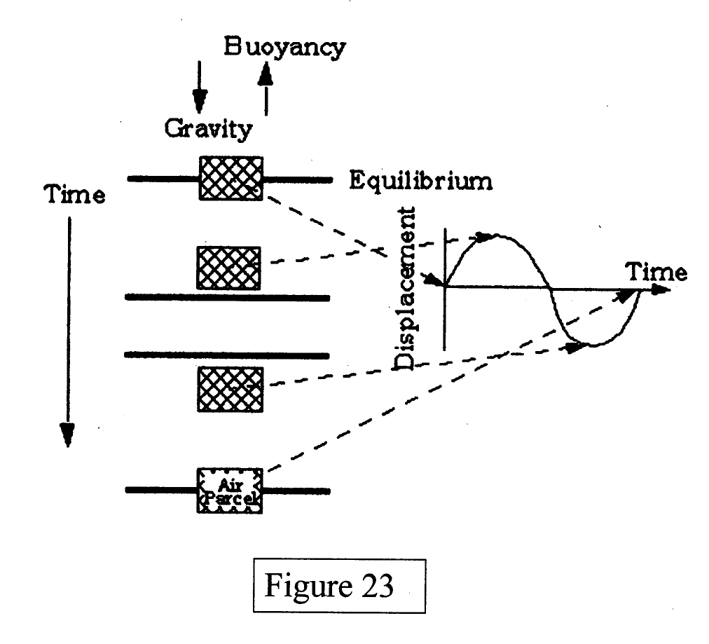

By modulating the power as a function of time, the heating pattern can generate gravitational waves. FIG. 23 is a schematic of the mechanism of gravitational wave generation in the atmosphere. This demonstrates oscillation of an air parcel, shown on the left, at four “snapshots” in time. The time for the parcel to return to its original position is the buoyancy period. The displacement curve on the right shows the wave motion of the air parcel with time. Generation of such waves will obviously take much more power than the communications applications.

It is intriguing to see the hints in the literature that the wave phenomena in the atmosphere, including instabilities of the waves, can have a major influence on weather patterns. Koch and Dorian, “A mesoscale gravity wave event observed during CCOPE”, Mon. Wea. Rev. 116, 2570-2592, 1988, observe gravity waves from a jet streak exit region, organizing a sequence of thunderstorms as they propagated through a region of weak conditional convective instability. Mesocyclone development is heavily dependent on the vorticity of steering winds. (See Xue ibid)

Quantitative analysis of the application of this air heating invention, requires use of these sophisticated computer simulations before quantitative predictions can be made. However, it is tantalizing to think that sufficient knowledge could be gained to use these techniques to mitigate the effects of severe weather. If a gravity wave can spawn thunderstorms, then it could be possible to redirect thunderstorm locations during development of a hurricane and take momentum and energy away from the main cyclonic motion of the storm. Tornadoes could be prevented by modifying the vorticity of the steering winds.

The apparatus could be built with conventional magnetrons or Klystrons, in systems that could be portable and moved to the site of the weather system. Individual phased array radiating elements could be mounted on emergency vehicles in the midwest, and multiple vehicles could be driven to appropriate locations to create a plasma pattern in the air, which can then be heated and redirect steering winds in mesocyclones. On a larger scale, individual phased array radiating elements could be mounted on buoys in the Atlantic off the coast of Africa and could be powered by solar energy. Hurricane mitigation could then be accomplished in the early stages of hurricane development.

Acoustic waves could also be important in influencing weather systems. They are readily absorbed in trophospheric weather systems. Acoustic energy associated with mesocyclones indicates a strong correlation with tornadic activity. (See Passner et al, “Acoustic energy measured from mesocyclones and tornadoes in June, 2003, Battlefield Environment Directorate, U.S. Army Research Laboratory, White Sands Missile Range, New Mexico.) Acoustic waves can be generated by the air heating plasma pattern by oscillating the heating beam at an appropriate acoustic frequency.

An air heating system could be relatively small, at level of 10⁶ watts with heating patterns of about 2,000 meter². Such small systems could be used to generate acoustic waves that could be absorbed in the tight steering wind patterns of a mesocyclone. The frequency of the acoustic waves could be from 1 Hz to 60 Hz.

Power levels of 10⁷ watts or more, with plasma pattern lengths of 5 to 10 km long at 12,000 meter altitudes, with a frequency from 1 Hz to weeks or more, could be considered for modifying the direction of the path of the jet stream. The heating time periods for generation of gravity waves could be range from hours, to days, or weeks.

Manipulation of Electrical Charge Distribution in Mesocyclones

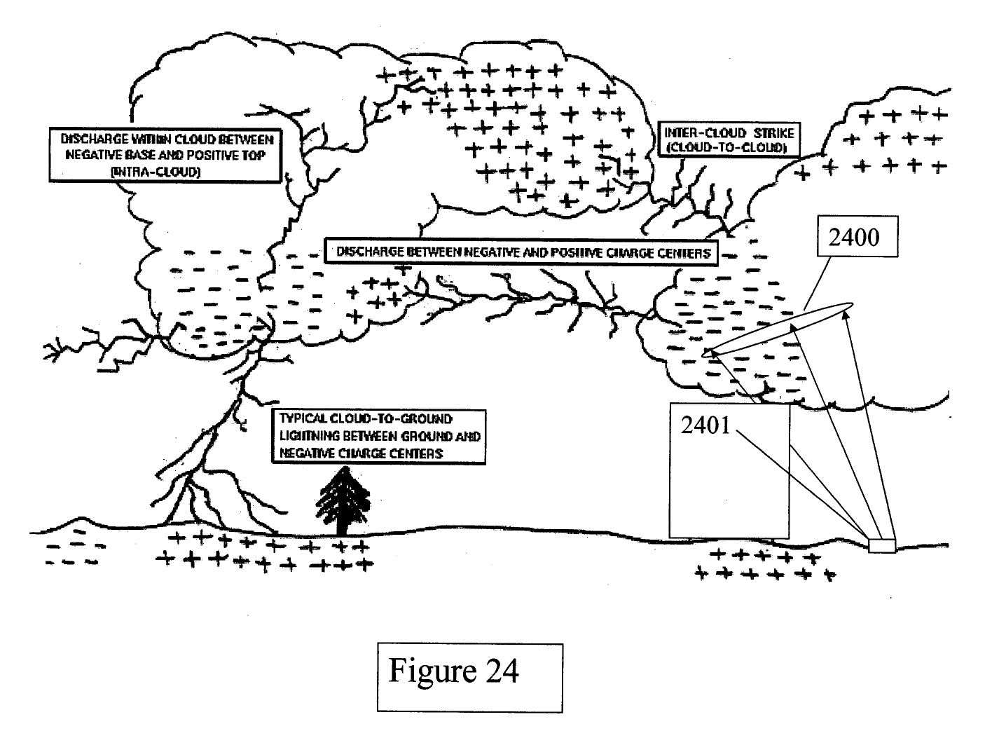

The method of using cosmic particle ignited plasma patterns to locally changing the electrical conductivity of the air in specific regions of a weather pattern and manipulate the electrical forces in the weather pattern is illustrated schematically in FIG. 24. FIG. 24 is a schematic illustration of cloud charge distribution in a mesocyclone. The method of this invention is to create a plasma pattern 2400, using an electromagnetic wave radiator 2401 which is electrically conducting in an auspicious region of the storm, to leak charge from one region to the other and thus, equalize electric forces. Electric fields in mesocyclones are being studied as possible facilitators of tornadogenesis. See, Patton et al, “A Possible Electric Force Facilitator for Tornadogenesis and Stability, Department of Physics, University of Oregon, Feb. 1, 2005. A general discussion of electric field profiles in severe thunderstorms has been written by Rust et al, “Aspects of Electric Field Profiles and Total Lightening in Severe Thunderstorms in Steps, NOAA/National Severe Storms Laboratory, Norman, Okla., 2005. The method of this invention can be both a research tool for study of such phenomena or eventually as a possible means of mitigating tornadogenesis.

Due to the rapid geographical motion of such systems, the individual radiating elements of the phased array of the electromagnetic wave radiator 2001 would be located on movable emergency vehicles.

Application to Lightening Protection for Golf Courses

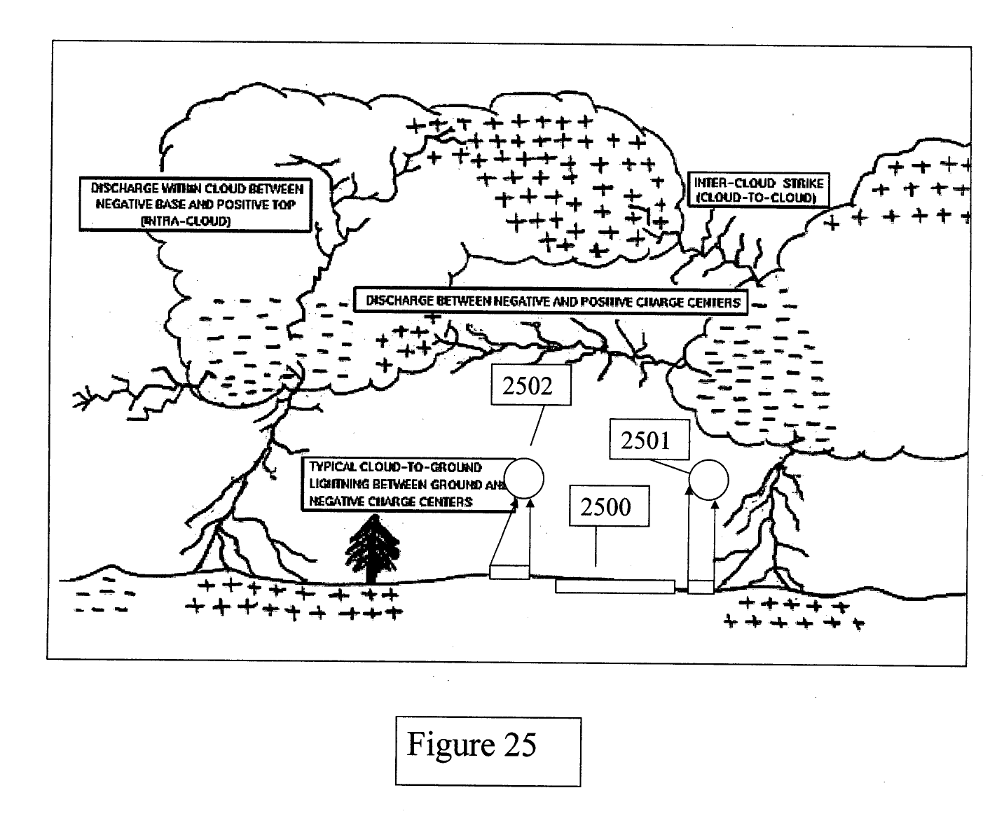

A practical near term application of utilizing the electrical conductivity of a plasma pattern to influence weather phenomena is as a lightening prevention mechanism for golf courses. FIG. 25 illustrates a mesocyclone over a golf course. In this case, two different plasma patterns, 2501 and 2501 would be established on each side of the golf course 2500. The purpose is to have the lightening jump between the two conducting surfaces rather than from the cloud to the ground.

Astronomy Application

Interference patterns generated by crossed electromagnetic wave radiator beams as illustrated in FIG. 3 have been suggested for use as guide stars for astrophysical telescopes. See Ribak et al, “Radio plasma fringes as guide stars: tracking the global tilt” Department of Physics, Technicon, Haifa, 2000.) The method of this patent to utilize cosmic particles to lower the power requirements could make such an application practical.

Defense Applications

Acceleration of electrons in the ionosphere to Mev energies was suggested by Eastlund in U.S. Pat. No. 5,038,664. A DARPA sponsored research effort to study mechanisms of creation of such Mev electrons by RF radiation in the 2 to 10 Mhz region resulted in a paper by Menyuk et al, “Stochastic Electron Acceleration in Obliquely Propagating Electromagnetic Waves”, Physical Review Letters, May 18, 1987. Such relativistic electrons created by ground based antenna systems have various military applications, including interdiction of missiles.

The power flux required for such mechanisms to accelerate electrons is about 500 milliwatts/cm². The HAARP antenna at its 3.6 Megawatt level can supply a flux of just 0.35 micro-watts/cm² at an altitude of 100 KM.

It has been suggested by Ka+w et al, “Gamma ray flashes by plasma effects in the middle atmosphere,” Physics of Plasmas, Vol. 8, No. 11, November, 2001 that stochastic electron acceleration could be a factor in runaway electron acceleration observed as a source of gamma ray flashes associated with thunderstorms and lightening.

The gamma particle ignited plasmas patterns described in this patent could be used to provide a platform for artificially accelerating electrons in the atmosphere. The lightening observations are associated with phenomena at 20 KM heights.

Another embodiment of this patent is to create a plasma pattern at 20 KM and to use the energetic electrons in the electron distribution of the plasma pattern as an initial set of electrons that are accelerated by a second beam of electromagnetic energy that is in the frequency range of 2 to 10 Hz. The initial electron energy could be further increased by heating it with a single billion watt pulse from a microwave generator as described by Vikharev ibid.

Menyuk et al determined the requirement of 500 milliwatts/cm² based on acceleration of a small number of low energy electrons. Thus, if the electrons in one of our plasma patterns already have some electrons above 100 ev or more, then the power requirement could be much lower. The HAARP antenna can produce about 9 microwatts/cm² at 20 KM as presently configured and could be used to verify this method of electron acceleration.

Emergency Communications Applications

Natural disasters, such as that of Aug. 29, 2005 of hurricane Katrina can eliminate cell phone surface over 90,000 square miles.

A principal embodiment of this invention is to provide a portable version of this invention that can be driven to a disaster area and set up in a matter of hours to provide cellular communication throughout the area.

The portable system would be sized with or either short haul or city wide cellular communications equipment and physical parameters.

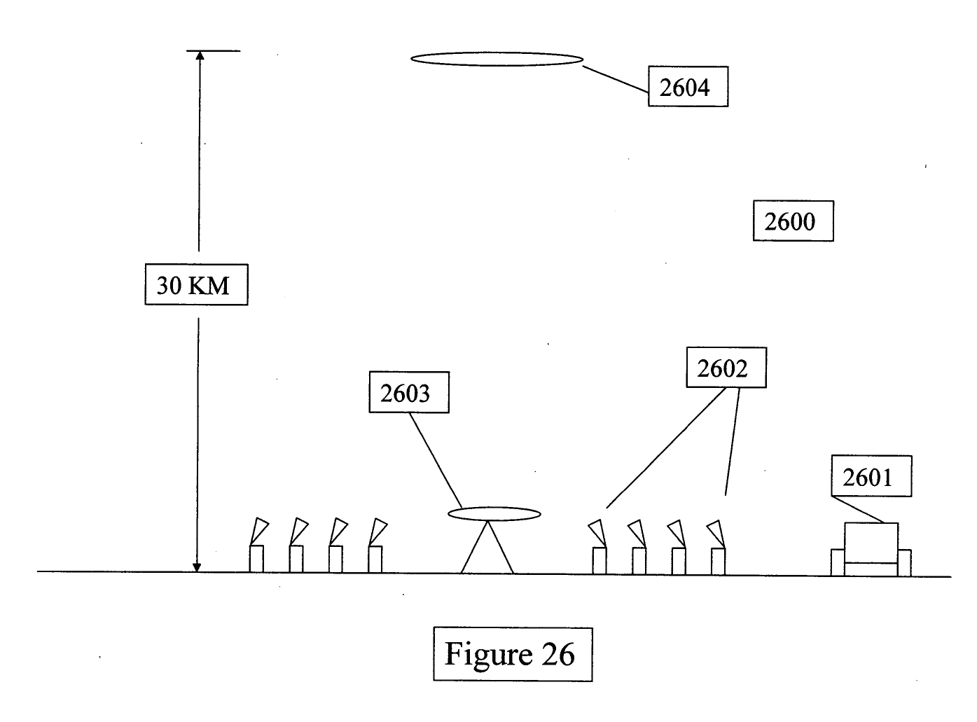

A schematic drawing of a portable system for cellular telecommunications is shown in FIG. 26. The system includes one or more portable electrical generators 2601, a cellular base station 2603, and multiple (between 100 and 1000) portable phased array radiating elements 2602. The radiating elements 2602 are coordinated by a control system located in the base station or in one of the elements. Communications to the radiating elements 2602 from the base station 2603 can be via Wi-Fi, electrical cable or optical fiber communications.

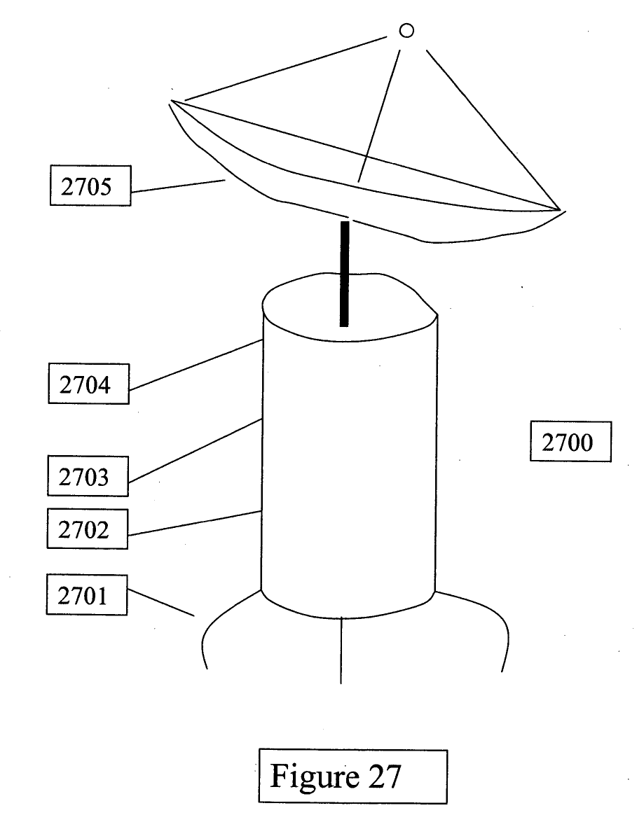

A schematic drawing of a portable phased array radiating element is shown in FIG. 27. FIG. 27 is a schematic drawing of a radiating element 2602. The radiating element is about 1 meter tall and the base is about 10 inches in diameter. The antenna 2705 is collapsible for shipment and expands to about 1 meter in diameter. The power supply 2702 is contained in a container and generates about 5 KW of electrical power to supply the electromagnetic wave generator 2703 also located in the container. The electromagnetic wave generator 2703 can be a magnetron or Klystron or other electromagnetic wave generator technology. A control system 2704, also located in the container points the individual antenna in a preferred direction to contribute to the focal properties of establishment of the electrical field pattern used to form a reflecting plasma pattern.

### CONCLUSION

This invention has a phenomenal variety of possible ramifications and potential future developments. As alluded to earlier, a variety of telecommunications systems for improvement of local cellular systems, short haul stand alone cellular systems, city wide cellular systems and long haul communications systems could result. Two new approaches to weather modification and control are suggested. The first is for manipulation of the steering winds that control the development of mesocyclones, or the modification of the directions of the jet streams that influence development of hurricanes. The second is a method for influencing the electrical charge distribution in weather patterns such as meso-cyclones. Possible defense applications include a method of accelerating electrons to MEV energies in conjunction with the HAARP antenna. Research applications include the creation of bright and controlled guide stars for astrophysical purposes. Thus it can be seen that the ramifications are numerous, far-reaching, and exceedingly varied in usefulness.

1. A method of creating one or more artificially ionized regions in the air called cosmic particle ignition by synchronizing the establishment of an electric field pattern at an altitude above the earth's surface with the natural occurrence of ionization trails created by cosmic particles within the electric field pattern comprising:
a. Detecting the position of the cosmic particle ionization trail with a detector array,
b. Triggering an electromagnetic wave radiator to establish an electric field pattern at the location of the ionization trail,
c. Holding the electric field pattern constant while the cosmic particle ionization trail ignites electrical breakdown of the air and fills the electric field pattern with plasma to create a plasma pattern,
whereby an artificially ionized plasma region is created with lower electric fields and consequently much lower power levels than required for electrical breakdown in ambient air.

2. An electromagnetic wave radiator apparatus for said cosmic particle ignition method of creating one or more artificially ionized regions in the air comprising:
a. a detector array for detecting the position and time of occurrence of a cosmic particle ionization trail at a desirable position,
b. an electromagnetic wave radiator that can be triggered to radiate,
c. a control system to hold the electric field strength constant while the breakdown process occurs and then to decrease the amplitude of the field pattern to a maintenance value of electric field strength.

3. The method of claim 1 wherein the cosmic particle is a primary cosmic ray or secondary cosmic ray electrons occurring at altitudes between sea level and 40,000 KM.

4. The method of claim 1 wherein the cosmic particle is a micrometeorite occurring at altitudes above 80,000 meters.

5. The method of claim 1 wherein the electric field pattern is established at altitudes between sea level and 100,000 meters above the earth's surface.

6. The apparatus of claim 2 wherein the electromagnetic wave radiator includes a phased array with multiple radiating elements.

7. The method of claim 1 wherein the plasma pattern is reconfigured in size, shape and position by varying the phase of said multiple radiating elements.

8. The apparatus of claim 2 wherein the detector system is an array of Geiger-Muller counters for detection of and determining the location of cosmic ray primary and secondary particle showers by detecting muons formed by the interaction of the primary and secondary particles with the atoms of the atmosphere.

9. The apparatus of claim 2 wherein the detection system is an array of VLF radars for detecting the ionization trail of micro-meteors by bouncing the VLF signal off the trail.

10. A method of creating one or more artificially ionized regions in the air by first establishing an electric field pattern at desired altitude above the earth's surface then waiting for the natural occurrence of ionization trails created by cosmic particles within the electric field pattern comprising:
a, establishing an electric field pattern at a desired altitude with an electromagnetic wave generator,
b. Holding the electric field pattern constant for a time period called the ignition time which is the time it takes for a cosmic particle to create an ionization trail within the electric field pattern,
c. Maintaining the electric field pattern constant while the cosmic particle ionization trail ignites a plasma within the electric field pattern to create a plasma pattern, whereby an artificially ionized plasma region is created with lower electric fields and consequently much lower power levels than required for electrical breakdown in ambient air.

11. The method of claim 10 wherein the electromagnetic wave radiator is a phased array antenna with multiple radiating elements for transmitting said electromagnetic waves through the air.

12. The method of claim 1 or claim 10 wherein a plasma pattern is established above 10,000 meters for enhancing telecommunications signals in existing cell phone tower systems.

13. The method of claim 1 or claim 10 wherein a plasma pattern is established above 10,000 meters for a short haul telecommunications system.

14. The method of claim 1 or claim 10 wherein a plasma pattern is established above 30,000 meters for creating a city wide telecommunications system.

15. The method of claim 1 or claim 10 wherein a plasma pattern with plasma patterns shaped like dual paraboloids are located in separate locations 1600 KM apart and at an altitude of over 80,000 meters for creating a long haul telecommunications system.

16. The method of claim 1 or claim 10 wherein the air is heated by irradiating a plasma pattern located above 10,000 meters with a second electromagnetic wave radiator.

17. The method of claim 16 wherein second electromagnetic wave radiator has a variable power level that is modulated at a frequency typical of atmospheric wave phenomena. For generation of acoustic waves, the frequency would be from about 1 Hz to 60 Hz. For gravitational waves, the frequency would be from 1 Hz to 1 oscillation period per week.

18. The method of claim 16 wherein the heated air can be used to control weather.

19. The method of claim 16 wherein the individual radiating elements are portable.
